(19) United States
(12) Patent Application Publication
(10) Pub. No.: US 2024/0194713 A1
(43) Pub. Date: Jun. 13, 2024

(54) IMAGE SENSOR

(71) Applicant: Samsung Electronics Co., Ltd., Suwon-si (KR)

(72) Inventors: Sangin BAE, Suwon-si (KR); YUN KI LEE, Suwon-si (KR); HYEYEON PARK, Suwon-si (KR)

(21) Appl. No.: 18/370,550

(22) Filed: Sep. 20, 2023

(30) Foreign Application Priority Data
Dec. 8, 2022 (KR) 10-2022-0170885
Mar. 13, 2023 (KR) 10-2023-0032742

(51) Int. Cl. H01L 27/146

(52) U.S. Cl. CPC H01L 27/14627; H01L 27/14645

(57) ABSTRACT

Disclosed is an image sensor comprising a first substrate including pixel sections each of which includes a photoelectric conversion region; a plurality of color filters on the pixel sections and on a first surface of the first substrate, and a plurality of microlenses on the color filters. An array of the microlenses includes a repetitive periodic structure. The periodic structure includes a first microlens, a second microlens, and a third microlens that are sequentially arranged adjacent to each other along a first direction. A first spacing in the first direction between the first and second microlenses is substantially the same as a second spacing in the first direction between the second and third microlenses. A first pitch in the first direction between the first and second microlenses is different from a second pitch in the first direction between the second and third microlenses.

### CROSS-REFERENCE TO RELATED APPLICATIONS

This U.S. nonprovisional application claims priority under 35 U.S.C § 119 to Korean Patent Applications No. 10-2022-0170885 filed on Dec. 8, 2022 and No. 10-2023-0032742 filed on Mar. 13, 2023 in the Korean Intellectual Property Office, the disclosures of each of which are hereby incorporated by reference in their entirety.

### BACKGROUND

An aspect of the present inventive concepts relate to an image sensor, and more particularly, to an image sensor of which an output has an improved quality and a method of fabricating the same.

An image sensor is a device to convert optical images into electrical signals. An image sensor can be classified into a charge coupled device (CCD) type and a complementary metal oxide semiconductor (CMOS) type. A CMOS type image sensor is abbreviated to CIS (CMOS image sensor). The CIS has a plurality of two-dimensionally arranged pixels. Each of the pixels includes a photodiode. The photodiode serves to convert incident light into electrical signals.

### SUMMARY

Some embodiments of inventive concepts provide an image sensor whose output has an improved quality.

According to some embodiments of the present inventive concepts, an image sensor may comprise: a first substrate including pixel sections each of which includes a photoelectric conversion region; a plurality of color filters on the pixel sections and on a first surface of the first substrate; and a plurality of microlenses on the color filters. The plurality of microlenses are arranged in an array of the microlenses with a periodic structure. The periodic structure may include a first microlens, a second microlens, and a third microlens that are sequentially arranged adjacent to each other along a first direction. A first spacing in the first direction between the first and second microlenses may be substantially the same as a second spacing in the first direction between the second and third microlenses. A first pitch in the first direction between the first and second microlenses may be different from a second pitch in the first direction between the second and third microlenses.

According to some embodiments of the present inventive concepts, an image sensor may comprise: a substrate including pixel sections each of which includes a photoelectric conversion region; a plurality of color filters on the pixel sections and on a first surface of the substrate; and a plurality of microlenses on the color filters. The microlenses may include first microlenses and second microlenses. The first and second microlenses may have different sizes from each other. The first and second microlenses may constitute a periodic structure of an M×N array where each of M and N is an integer equal to or greater than 3. A first edge lens on a first side of the periodic structure may be offset in a first direction from a pixel center that corresponds to the first edge lens. A second edge lens on a second side of the periodic structure may be offset in a direction from a pixel center that corresponds to the second edge lens. The direction may be reverse to the first direction.

According to some embodiments of the present inventive concepts, an image sensor may comprise: a circuit chip; and an image sensor chip on the circuit chip. The image sensor chip may include: a first substrate that has a first surface and a second surface that are opposite to each other and includes photoelectric conversion regions therein; a separation pattern in the first substrate and defining pixel sections, the photoelectric conversion regions being correspondingly provided in the pixel sections; a dielectric layer that covers the first surface; a plurality of color filters on the dielectric layer; a fence pattern that divides the color filers; a protective layer between the fence pattern the color filters; a plurality of microlenses on the color filters; a lens coating layer on the microlenses; a device isolation pattern adjacent to the second surface, the device isolation pattern defining an active region; a buried gate pattern on the second surface; and a first wiring layer on the buried gate pattern. The circuit chip may include: a second substrate on which integrated circuits are provided; and a second wiring layer on the second surface. The first wiring layer and the second wiring layer may be electrically connected with each other while facing each other. The microlenses may constitute a periodic structure of an M×N array where each of M and N is an integer equal to or greater than 3. A center of a first microlens of the periodic structure may be offset in a first direction from a pixel center of a first pixel corresponding to the first microlens. A center of a second microlens of the periodic structure may be offset from a pixel center of a second pixel corresponding to the second microlens in an opposite direction of the first direction.

### BRIEF DESCRIPTION OF DRAWINGS

FIG. 1 illustrates a circuit diagram showing a pixel of an image sensor according to some embodiments of the present inventive concepts.

FIG. 2 illustrates a plan view showing an image sensor according to some embodiments of the present inventive concepts.

FIG. 3 illustrates a cross-sectional view taken along line I-I′ of FIG. 2.

FIG. 4 illustrates a cross-sectional view taken along line I-I′ of FIG. 2 which shows an image sensor according to some embodiments of the present inventive concepts.

FIG. 5 illustrates a cross-sectional view taken along line II-II′ of FIG. 2 which shows an image sensor according to some embodiments of the present inventive concepts.

FIG. 6 illustrates a plan view of section M of FIG. 2 which shows an image sensor according to some embodiments of the present inventive concepts.

FIG. 7 illustrates a cross-sectional view taken along line I-I′ of FIG. 6.

FIG. 8 illustrates a plan view of section M of FIG. 2 which shows an image sensor according to some embodiments of the present inventive concepts.

FIG. 9 illustrates a cross-sectional view taken along line I-I′ of FIG. 8.

FIG. 10 illustrates a plan view of section M of FIG. 2 which shows an image sensor according to some embodiments of the present inventive concepts.

FIG. 11 illustrates a cross-sectional view taken along line I-I′ of FIG. 10.

FIGS. 12, 13, and 14 illustrate cross-sectional views showing a difference between a first microlens and a second microlens according to some embodiments of the present inventive concepts.

FIG. 15 illustrates a plan view of section M of FIG. 2 which shows an image sensor according to some embodiments of the present inventive concepts.

FIG. 16A illustrates a cross-sectional view taken along line I-I′ of FIG. 15.

FIG. 16B illustrates a cross-sectional view taken along line II-II′ of FIG. 15.

FIG. 17 illustrates a plan view of section M of FIG. 2 which shows an image sensor according to some embodiments of the present inventive concepts.

FIG. 18 illustrates a plan view of section M of FIG. 2 which shows an image sensor according to some embodiments of the present inventive concepts.

FIG. 19 illustrates a cross-sectional view taken along line I-I′ of FIG. 18.

FIG. 20 illustrates a plan view of section M of FIG. 2 which shows an image sensor according to some embodiments of the present inventive concepts.

FIG. 21 illustrates a cross-sectional view taken along line I-I′ of FIG. 20.

FIG. 22 illustrates a plan view of section M of FIG. 2 which shows an image sensor according to some embodiments of the present inventive concepts.

FIG. 23 illustrates a cross-sectional view taken along line I-I′ of FIG. 22.

FIG. 24 illustrates an enlarged view showing a periodic structure of FIG. 22 according to some embodiments of the present inventive concepts.

FIGS. 25, 26, and 27 illustrate plan views showing an arrangement of color filters in an image sensor according to some embodiments of the present inventive concepts.

### DETAILED DESCRIPTION OF EMBODIMENTS

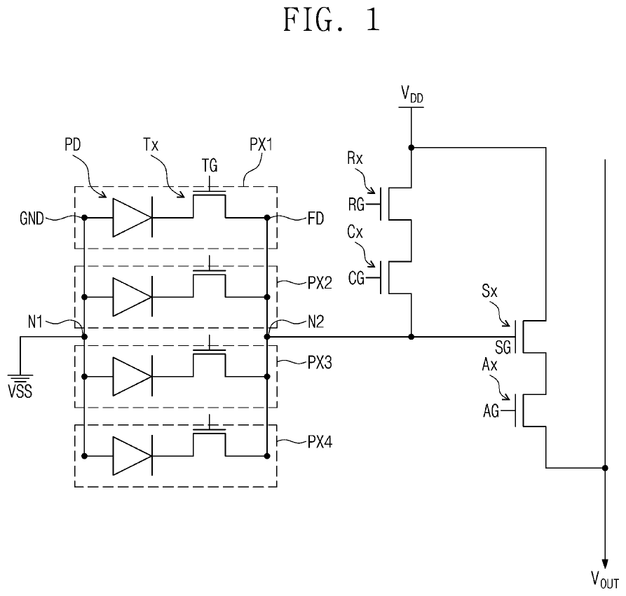

FIG. 1 illustrates a circuit diagram showing a pixel of an image sensor according to some embodiments of the present inventive concepts.

Referring to FIG. 1, an image sensor may include first to fourth pixels PX1 to PX4. Each of the first to fourth pixels PX1 to PX4 may include a ground region GND, a photoelectric conversion region PD, a transfer transistor Tx, and a floating diffusion region FD.

The ground region GND may include or may be a p-type impurity region. A ground voltage VSS may be applied in common through a first node N1 to the ground regions GND of the first to fourth pixels PX1 to PX4.

The photoelectric conversion region PD may be a photodiode that includes an n-type impurity region and a p-type impurity region. The floating diffusion region FD may include or may be an n-type impurity region. The floating diffusion region FD may serve as a drain of the transfer transistor Tx.

The floating diffusion regions FD of the first to fourth pixels PX1 to PX4 may be connected in common to a second node N2. The second node N2 to which are connected the floating diffusion regions FD of the first to fourth pixels PX1 to PX4 may be connected to a source of a conversion gain transistor Cx. The conversion gain transistor Cx may be connected to a reset transistor Rx.

The second node N2 may also be electrically connected to a source follower gate SG of a source follower transistor Sx. The source follower transistor Sx may be connected to a selection transistor Ax.

An operation of the image sensor will be explained below with reference to FIG. 1. First, a power voltage VDD may be applied to a drain of the reset transistor Rx and a drain of the source follower transistor Sx under a light-blocked state, such that the reset transistor Rx may be turned on to discharge charges that remain in the floating diffusion region FD. Thereafter, when the reset transistor Rx is turned off and external light is incident on the photoelectric conversion region PD, electron-hole pairs may be generated from the photoelectric conversion region PD. Holes may be transferred to and accumulated in a p-type impurity region of the photoelectric conversion region PD, and electrons may be transferred to and accumulated in an n-type impurity region of the photoelectric conversion region PD. When the transfer transistor Tx is turned on, charges such as electrons and holes may be transferred to and accumulated in the floating diffusion region FD. A gate bias of the source follower transistor Sx may change in proportion to an amount of the accumulated charges. The accumulated charges may change a source potential level (i.e., a source voltage) of the source follower transistor Sx. In this case, when the selection transistor Ax is turned on, charges may be read out as signals transmitted through a column line.

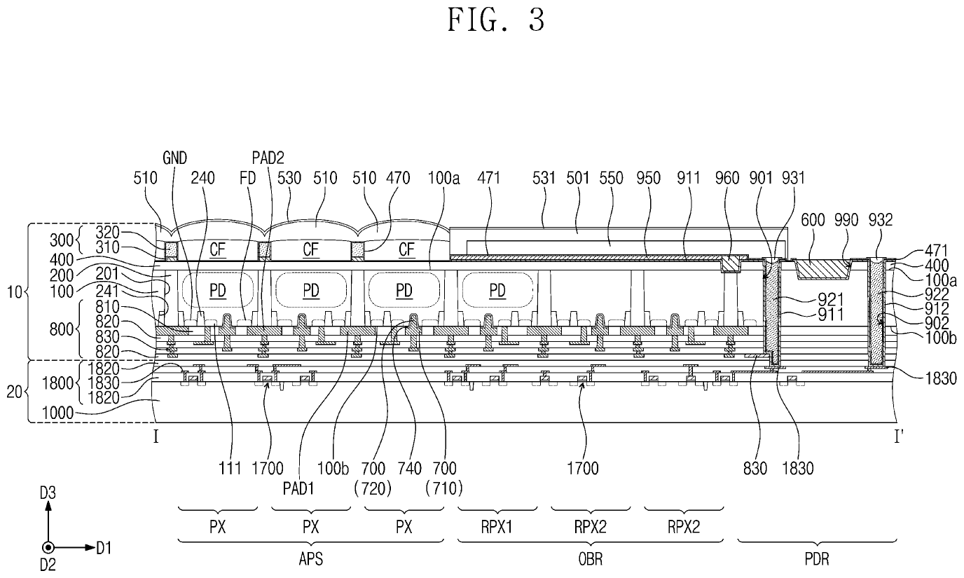

A wiring line may be electrically connected to at least one selected from a transfer gate TG, a source follower gate SG, a reset gate RG, and a selection gate AG. The wiring line may be configured to apply the power voltage VDD to the drain of the reset transistor Rx or the drain of the source follower transistor Sx. The wiring line may include a column line connected to the selection transistor Ax. The wiring line may include a first conductive structure 830 which will be discussed with respect to FIG. 3.

FIG. 1 depicts by way of example the first to fourth pixels PX1 to PX4 that share the first node N1 and the second node N2, but the present inventive concepts are not limited thereto.

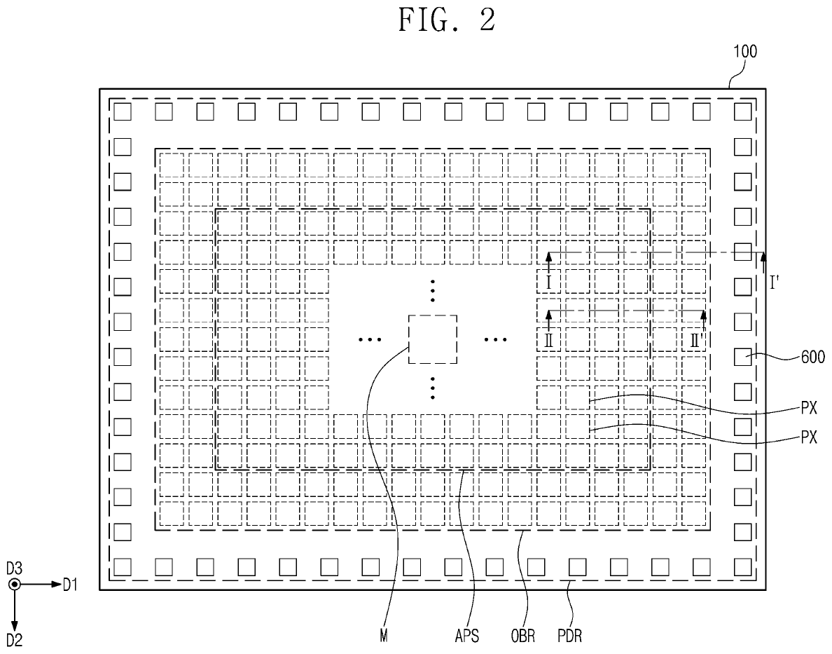

FIG. 2 illustrates a plan view showing an image sensor according to some embodiments of the present inventive concepts. FIG. 3 illustrates a cross-sectional view taken along line I-I′ of FIG. 2.

Referring to FIGS. 2 and 3, an image sensor may include a sensor chip 10. The sensor chip 10 may include a first substrate 100, a first wiring layer 800, a dielectric layer 400, a protective layer 470, color filters CF, a fence pattern 300, and a microlens layer 500.

When viewed in a plan view, the first substrate 100 may include a pixel array zone APS, an optical black zone OBR, and a pad zone PDR. The pixel array zone APS may be disposed on a central portion of the first substrate 100. The pixel array zone APS may include a plurality of pixel sections PX. The pixel discussed with reference to FIG. 1 may be provided to each of the pixel sections PX of the first substrate 100. For example, components included in the pixel of FIG. 1 may be provided on the pixel section PX. The pixel sections PX may output photoelectric signals from incident light.

The pixel sections PX may be two-dimensionally arranged in rows and columns. The rows may be parallel to a first direction D1. The columns may be parallel to a second direction D2. In this description, the first direction D1 may be parallel to a first surface 100a of the first substrate 100. The second direction D2 may be parallel to the first surface 100a of the first substrate 100 and may intersect the first direction D1. For example, the second direction D2 may be substantially orthogonal to the first direction D1. A third direction D3 may be perpendicular to the first direction D1 and the second direction D2. For example, the third direction D3 may be substantially perpendicular to the first surface 100a of the first substrate 100.

The pad zone PDR may surround the pixel array zone APS, while being provided on an edge portion of the first substrate 100. The pad zone PDR may be provided with pads PAD thereon. The pads PAD may externally output electrical signals generated from the pixel sections PX. Alternatively, external electrical signals or voltages may be transferred through the pads PAD to the pixel sections PX. As the pad zone PDR is disposed on the edge portion of the first substrate 100, the pads PAD may be easily coupled to an external apparatus. The optical black zone OBR will be described below. The following description will focus on the pixel array zone APS of the sensor chip 10 included in the image sensor.

The first substrate 100 may have a first surface 100a and a second surface 100b that are opposite to each other. The first surface 100a may be a rear surface of the first substrate 100, and the second surface 100b may be a front surface of the first substrate 100. External light may illuminate on the first surface 100a of the first substrate 100. The first substrate 100 may be a semiconductor substrate or a silicon-on-insulator (SOI) substrate. The semiconductor substrate may include or may be formed of, for example, a silicon substrate, a germanium substrate, or a silicon-germanium substrate. The first substrate 100 may further include a III-group element. The III-group element may be an impurity having a first conductivity type. For example, the first substrate 100 may have the first conductivity type, for example, p-type. For example, impurities having the first conductivity type may include one or more of aluminum (Al), boron (B), indium (In), and gallium (Ga).

The first substrate 100 may include a plurality of photoelectric conversion regions PD therein. The photoelectric conversion regions PD may be positioned between the first surface 100a and the second surface 100b of the first substrate 100. The photoelectric conversion regions PD may be correspondingly disposed in the pixel sections PX of the first substrate 100. The photoelectric conversion region PD of FIG. 3 may be the same as the photoelectric conversion region PD of FIG. 1.

The photoelectric conversion region PD may further include a V-group element. The V-group element may be an impurity having a second conductivity type. For example, the photoelectric conversion region PD may be an impurity region having the second conductivity type. The second conductivity type may be an n-type different from the first conductivity type. The impurities having the second conductivity type may include one or more of phosphorus, arsenic, bismuth, and antimony. The photoelectric conversion region PD may be adjacent to the first surface 100a of the first substrate 100. The photoelectric conversion region PD may extend from the first surface 100a toward the second surface 100b.

The first substrate 100 may be provided therein with a separation pattern 200 that defines the pixel sections PX. For example, the separation pattern 200 may be provided between neighboring pixel sections PX. The separation pattern 200 may be a pixel isolation pattern. The separation pattern 200 may be provided in a first trench 201. The first trench 201 may be recessed from the second surface 100b toward the first surface 100a of the first substrate 100.

The separation pattern 200 may be a deep trench isolation (DTI) layer. According to the present embodiment, the separation pattern 200 may penetrate the first substrate 100. According to some embodiments of the present inventive concepts, the separation pattern 200 may not penetrate the first substrate 100 and may be spaced apart from the first surface 100a of the first substrate 100. A width of the separation pattern 200 adjacent to the second surface 100b may be greater than that of the separation pattern 200 adjacent to the first surface 100a.

The color filters CF that locate on corresponding pixel sections PX may be provided on the first surface 100a of the first substrate 100. For example, the color filters CF may be provided on positions that correspond to the photoelectric conversion regions PD. The color filters CF may vertically overlap the photoelectric conversion regions PD, respectively. In some embodiments of the present inventive concepts, each of the color filters CF may include or may be one of a red filter, a blue filter, and a green filter. The color filters CF may constitute color filter arrays. For example, the color filters CF may be two-dimensionally arranged in Bayer pattern format.

In some embodiments of the present inventive concepts, the color filters CF may further include a white filter. For example, the color filters CF may include a red filter, a blue filter, a green filter, and a white filter that are two-dimensionally arranged.

The fence pattern 300 may be disposed on the separation pattern 200. For example, the fence pattern 300 may vertically overlap the separation pattern 200. The fence pattern 300 may be interposed between and separate two neighboring color filters CF. For example, the fence pattern 300 may physically and optically separate the color filters CF from each other.

The fence pattern 300 may have a planar shape that corresponds to that of the separation pattern 200. For example, the fence pattern 300 may have a grid shape. When viewed in a plan view, the fence pattern 300 may surround each of the pixel sections PX. The fence pattern 300 may surround each of the color filters CF. The fence pattern 300 may include first segments and second segments. The first segments may extend parallel to the first direction D1 and may be spaced apart from each other in the second direction D2. The second segments may extend parallel to the second direction D2 and may be spaced apart from each other in the first direction D1. The second segments may intersect the first segments to form the grid shape.

The fence pattern 300 may include a first fence pattern 310 and a second fence pattern 320. The first fence pattern 310 may be disposed between the dielectric layer 400 and the second fence pattern 320. The first fence pattern 310 may include or may be formed of a conductive material such as metal and metal nitride. For example, the first fence pattern 310 may include at least one of titanium and titanium nitride.

The second fence pattern 320 may be disposed on the first fence pattern 310. The second fence pattern 320 may include or may be formed of a different material from that of the first fence pattern 310. The second fence pattern 320 may include or may be formed of an organic material. The second fence pattern 320 may include or may be formed of a material of which a refractive index is low and may have dielectric characteristics. For example, the second fence pattern 320 may include or may be formed of a non-conductive organic material with a low refractive index.

The dielectric layer 400 may be interposed between the first substrate 100 and the color filters CF and between the separation pattern 200 and the fence pattern 300. The dielectric layer 400 may cover the first surface 100a of the first substrate 100 and a top surface of the separation pattern 200. The dielectric layer 400 may be a backside dielectric layer. The dielectric layer 400 may include a bottom antireflective coating (BARC) layer. The dielectric layer 400 may include a plurality of layers, which layers may have different functions from each other.

In some embodiments of the present inventive concepts, the dielectric layer 400 may include a first dielectric layer, a second dielectric layer, a third dielectric layer, a fourth dielectric layer, and a fifth dielectric layer that are sequentially stacked on the first surface 100a of the first substrate 100. The first dielectric layer may cover the first surface 100a of the first substrate 100. The first and second dielectric layers may be fixed charge layers. Each of the fixed charge layers may include a metal oxide layer and a metal fluoride layer. The metal oxide layer may include oxygen of which an amount is less than a stoichiometric ratio, and the metal fluoride layer may include fluorine of which an amount is less than a stoichiometric ratio.

For example, the first dielectric layer may include or may be formed of metal oxide or metal fluoride that includes at least one metal selected from hafnium (Hf), zirconium (Zr), aluminum (Al), tantalum (Ta), titanium (Ti), yttrium (Y), and lanthanide. The second dielectric layer may include or may be formed of one of metal oxide and metal fluoride that are discussed in the example of the first dielectric layer. However, the second dielectric layer may include or may be formed of a different material from that of the first dielectric layer. For example, the first dielectric layer may include or may be formed of aluminum oxide, and the second dielectric layer may include or may be formed of hafnium oxide.

Each of the first and second dielectric layers may have a negative fixed charge and may produce hole accumulation. The first and second dielectric layers may effectively reduce white spot and dark current of the first substrate 100. The second dielectric layer may have a thickness greater than that of the first dielectric layer.

The third dielectric layer may be disposed on the second dielectric layer. The third dielectric layer may include or may be formed of a first silicon-containing material. The first silicon-containing material may include, for example, tetraethyl orthosilicate (TEOS) or silicon oxide. The third dielectric layer may have good filling characteristics. The third dielectric layer may be formed by plasma enhanced chemical vapor deposition, but the present inventive concepts are not limited thereto. The third dielectric layer may have a thickness greater than that of the first dielectric layer and that of the second dielectric layer.

The fourth dielectric layer may be disposed on the third dielectric layer. The fourth dielectric layer may include or may be formed of a different material from that of the third dielectric layer. The fourth dielectric layer may include or may be formed of a second silicon-containing material, and the second silicon-containing material may be different from the first silicon-containing material. For example, the fourth dielectric layer may include or may be formed of silicon nitride. The fourth dielectric layer may have a thickness greater than that of the third dielectric layer.

The fifth dielectric layer may be disposed between the fourth dielectric layer and the first fence pattern 310 and between the fourth dielectric layer and the color filters CF. The fifth dielectric layer may be in physical contact with a bottom surface of the first fence pattern 310. The fifth dielectric layer may be an adhesive layer or a capping layer. The fifth dielectric layer may include or may be formed of a high-k dielectric material or metal oxide. The fifth dielectric layer may include or may be formed of the same material as that of the second dielectric layer. For example, the fifth dielectric layer may include or may be formed of hafnium oxide. The fifth dielectric layer may have a thickness greater than that of each of the first and second dielectric layers and less than that of each of the third and fourth dielectric layers.

Differently from the embodiment discussed in detail above, the number of layers included in the dielectric layer 400 may be variously changed. For example, at least one of the first to fifth dielectric layers may be omitted.

The protective layer 470 may cover the dielectric layer 400 and the fence pattern 300. In some embodiments, the protective layer 470 may conformally cover the dielectric layer 170 and the fence pattern 300. The protective layer 470 may include or may be formed of a high-k dielectric material and may have dielectric characteristics. For example, the protective layer 470 may include or may be formed of aluminum oxide or hafnium oxide. For more detail, the protective layer 470 may include or may be formed of aluminum oxide, but the present inventive concepts are not limited thereto. The protective layer 470 may protect the photoelectric conversion region PD of the first substrate 100 against external environment such as moisture.

The color filters CF may be provided on the protective layer 470. The fence pattern 300 may separate the color filters CF from each other. An uppermost surface of the color filter CF may be coplanar with a top surface of the fence pattern 300. Alternatively, the uppermost surface of the color filter CF may be higher than the top surface of the fence pattern 300.

The microlens layer 500 may be provided on the first surface 100a of the first substrate 100. For example, the microlens layer 500 may be provided on the color filters CF. The protective layer 470 may be provided between the second fence pattern 320 and the microlens layer 500.

The microlens layer 500 may include a plurality of convex microlenses 510. The microlenses 510 may be correspondingly provided on positions that corresponds to the photoelectric conversion regions PD of the first substrate 100. The microlenses 510 may vertically overlap the photoelectric conversion regions PD, respectively. For example, the microlenses 510 may be provided on and correspond to the color filters CF. The microlenses 510 may vertically overlap the color filters CF. When viewed in a plan view, the microlenses 510 may be arranged along the first direction D1 and the second direction D2. Each of the microlenses 510 may protrude away from the first surface 100a of the first substrate 100. Each of the microlenses 510 may have a hemispheric cross-section. The microlenses 510 may concentrate incident light.

The microlens layer 500 may be transparent to light. The microlens layer 500 may include or may be formed of an organic material, such as a polymer. For example, the microlens layer 500 may include or may be formed of a photoresist material or a thermosetting resin.

A lens coating layer 530 may be provided on the microlens layer 500. The lens coating layer 530 may be transparent. The lens coating layer 530 may conformally cover a top surface of the microlens layer 500. The lens coating layer 530 may protect the microlens layer 500.

The first substrate 100 may include a ground region GND, a floating diffusion region FD, and an impurity region 111 that are adjacent to the second surface 100b. The ground region GND, the floating diffusion region FD, and the impurity region 111 may be disposed in each of the pixel sections PX. The ground region GND, the floating diffusion region FD, and the impurity region 111 may have bottom surfaces each of which is vertically spaced apart from the photoelectric conversion region PD.

The ground region GND may be heavily doped with impurities to have a first conductivity type (e.g., p+ type). The floating diffusion region FD and the impurity region 111 may each be doped with impurities to have a second conductivity type (e.g., n-type).

The impurity region 111 may be an active region for operation of a transistor. The impurity region 111 may include or may be a source/drain region of at least one selected from the conversion gain transistor Cx, the reset transistor Rx, the source/follower transistor Sx, and the selection transistor Ax that are discussed with reference to FIG. 1.

A device isolation pattern 240 may be provided which is adjacent to the second surface 100b of the first substrate 100. The device isolation pattern 240 may define an active region in the pixel section PX. For example, in the pixel section PX, the device isolation pattern 240 may define the ground region GND, the floating diffusion region FD, and the impurity region 111.

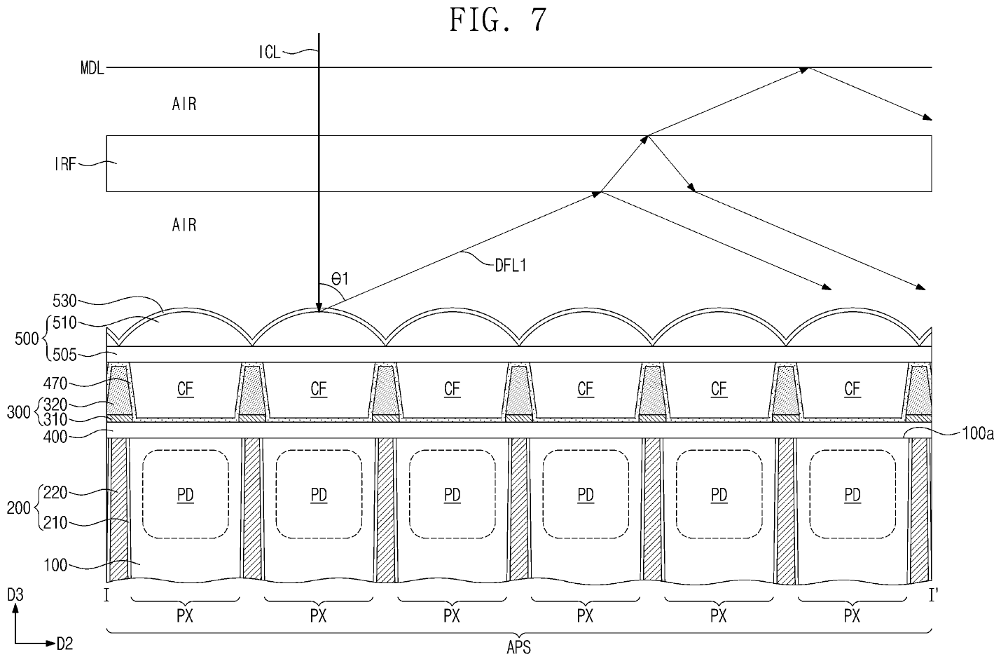

The device isolation pattern 240 may be provided in a second trench 241, and the second trench 241 may be recessed from the second surface 100b of the first substrate 100. The device isolation pattern 240 may be a shallow trench isolation (STI) layer. The device isolation pattern 240 may have a depth less than that of the separation pattern 200. A portion of the device isolation pattern 240 may be connected to a sidewall of the first separation pattern 210 which will be discussed with reference to FIG. 7. The device isolation pattern 240 may include or may be formed of, for example, at least one of silicon oxide, silicon nitride, and silicon oxynitride.

A buried gate pattern 700 may be provided on the second surface 100b of the first substrate 100. The buried gate pattern 700 may include the transfer gate TG of the transfer transistor Tx discussed above in FIG. 1. Although not shown in FIG. 3, at least one additional gate pattern may be provided on each of the pixel sections PX.

The additional gate pattern may serve as a gate electrode of at least one selected from the conversion gain transistor Cx, the source follower transistor Sx, the reset transistor Rx, and the selection transistor Ax that are discussed above in FIG. 1. For example, the additional gate pattern may include one of the conversion gain gate CG, the source follower gate SG, the reset gate RG, and the selection gate AG.

The buried gate pattern 700 may have a buried type gate structure. For example, the buried gate pattern 700 may include a first part 710 and a second part 720. The first part 710 of the buried gate pattern 700 may be disposed on the second surface 100b of the first substrate 100. The second part 720 of the buried gate pattern 700 may be buried in the first substrate 100. The second part 720 of the buried gate pattern 700 may be connected to the first part 710 of the buried gate pattern 700. Differently from that shown, the buried gate pattern 700 may have a planar gate structure. In this case, the buried gate pattern 700 may not include the second part 720. The buried gate pattern 700 may include or may be formed of metal, metal silicide, polysilicon, or a combination thereof. The polysilicon may include or may be formed of doped polysilicon.

A gate dielectric pattern 740 may be interposed between the buried gate pattern 700 and the first substrate 100. The gate dielectric pattern 740 may include or may be formed of, for example, at least one of a silicon-based dielectric material (e.g., silicon oxide, silicon nitride, and/or silicon oxynitride) and a high-k dielectric material (e.g., hafnium oxide and/or aluminum oxide).

A first pad PAD1 may be provided on the ground region GND. The first pad PAD1 may be provided on the ground regions GND of neighboring pixel sections PX and may connect the ground regions with each other. The first pad PAD1 may include the first node N1 discussed in FIG. 1.

A second pad PAD2 may be provided on the floating diffusion region FD. The second pad PAD2 may be provided on the floating diffusion regions FB of neighboring pixel sections PX and may electrically connect the floating diffusion regions FB with each other. The second pad PAD2 may include the second node N2 discussed in FIG. 1.

The first and second pads PAD1 and PAD2 may include or may be formed of metal, metal silicide, polysilicon, or a combination thereof. For example, the first and second pads PAD1 and PAD2 may include or may be formed of doped polysilicon.

The first wiring layer 800 may be disposed on the second surface 100b of the first substrate 100. The first wiring layer 800 may include a first interlayer dielectric layer 810, second interlayer dielectric layers 820, and a first conductive structure 830. The first interlayer dielectric layer 810 may cover the buried gate pattern 700 and the second surface 100b of the first substrate 100. The second interlayer dielectric layers 820 may be stacked on the first interlayer dielectric layer 810. The first and second interlayer dielectric layers 810 and 820 may include or may be formed of a silicon-based dielectric material, for example, silicon oxide, silicon nitride, and/or silicon oxynitride.

A first conductive structure 830 may be provided in the interlayer dielectric layers 810 and 820. The first conductive structure 830 may include contacts, wiring lines, and vias. The contact of the first conductive structure 830 may be provided in the first interlayer dielectric layer 810 and connected to at least one selected from the buried gate pattern 700, the first pad PAD1, the second pad PAD2, and the impurity region 111. The wiring line of the first conductive structure 830 may be connected to the contact of the first conductive structure 830. The via of the first conductive structure 830 may penetrate at least one of the second interlayer dielectric layers 820 and connect one of the wiring lines that are vertically adjacent to each other to the other. The first conductive structure 830 may receive photoelectric signals that are output from the photoelectric conversion regions PD.

The following will describe a circuit chip 20 of the image sensor and will also describe the optical black zone OBR and the pad zone PDR of the first substrate 100. Referring back to FIGS. 2 and 3, the optical black zone OBR of the first substrate 100 may be interposed between the pixel array zone APS and the pad zone PDR. The optical black zone OBR may include a first reference pixel section RPX1 and a second reference pixel section RPX2. The first reference pixel section RPX1 may be disposed between the second reference pixel section RPX2 and the pixel array zone APS. On the optical black zone OBR, the photoelectric conversion region PD may be provided in the first reference pixel section RPX1. The photoelectric conversion region PD on the first reference pixel section RPX1 may have a planar area and a volume that are the same as those of each of the photoelectric conversion regions PD on the pixel section PX. The photoelectric conversion region PD may not be provided on the second reference pixel section RPX2. The impurity regions 111, the buried gate pattern 700, and the device isolation pattern 240 may be disposed on each of the first and second reference pixel sections RPX1 and RPX2.

The dielectric layer 400 may extend from the pixel array zone APS through the optical black zone OBR onto the pad zone PDR. A light-shield layer 950 may be provided on the optical black zone OBR. The light-shield layer 950 may be disposed on a top surface of the dielectric layer 400. The light-shield layer 950 may prevent light from entering the photoelectric conversion region PD on the optical black zone OBR. On the optical black zone OBR, pixels of the first and second reference pixel sections RPX1 and RPX2 may output noise signals without outputting photoelectric signals. The noise signals may be generated from electrons produced due to heat or dark current. The light-shield layer 950 may not cover the pixel array zone APS, and thus light may be incident on the photoelectric conversion regions PD on the pixel array zone APS. The noise signals may be removed from photoelectric signals that are output from the pixel sections PX. The light-shield layer 950 may include or may be formed of metal, such as tungsten, copper, aluminum, and an alloy thereof.

On the optical black zone OBR of the first substrate 100, a first conductive pattern 911 may be disposed between the dielectric layer 400 and the light-shield layer 950. The first conductive pattern 911 may serve as a barrier layer or an adhesive layer. The first conductive pattern 911 may include at least one of metal and metal nitride. For example, the first conductive pattern 911 may include or may be formed of metal, such as copper, tungsten, aluminum, titanium, tantalum, and an alloy thereof. The first conductive pattern 911 may not extend onto the pixel array zone APS of the first substrate 100.

On the optical black zone OBR of the first substrate 100, a contact plug 960 may be provided on the first surface 100a of the first substrate 100. The contact plug 960 may be disposed on an outermost separation pattern 200 in the optical black zone OBR. The first substrate 100 may be provided on the first surface 100a with a contact trench that penetrates the dielectric layer 400, and the contact plug 960 may be provided in the contact trench.

The contact plug 960 may include a different material from that of the light-shield layer 950. For example, the contact plug 960 may include or may be formed of metal such as aluminum. The first conductive pattern 911 may extend between the contact plug 960 and the dielectric layer 400 and between the contact plug 960 and the separation pattern 200.

A protective dielectric layer 471 may be provided on the optical black zone OBR. The protective dielectric layer 471 may be disposed on a top surface of the light-shield layer 950 and a top surface of the contact plug 960. The protective dielectric layer 471 may include or may be formed of the same material as that of the protective layer 470 and may have a connection with the protective layer 470. The protective dielectric layer 471 may be integrally formed with the protective layer 470. Alternatively, the protective dielectric layer 471 may be formed by a process separate from that used for forming the protective layer 470, and may be spaced apart from the protective layer 470. The protective dielectric layer 471 may include or may be formed of a high-k dielectric material (e.g., aluminum oxide and/or hafnium oxide).

A filtering layer 550 may further be disposed on the first surface 100a on the optical black zone OBR. The filtering layer 550 may cover a top surface of the protective dielectric layer 471. The filtering layer 550 may block light of which a wavelength is different from that of light produced from the color filters CF. For example, the filtering layer 550 may block an infrared ray. The filtering layer 550 may include a blue color filter, but the present inventive concepts are not limited thereto.

An organic layer 501 may be provided on a top surface of the filtering layer 550. The organic layer 501 may be transparent. A top surface of the organic layer 501 may be substantially flat. For example, the organic layer 501 may include or may be formed of a polymer. The organic layer 501 may have dielectric characteristics. According to some embodiments of the present inventive concepts, differently from that shown, the organic layer 501 may be connected to the microlens layer 500. The organic layer 501 may include or may be formed of the same material as that of the microlens layer 500.

A coating layer 531 may be provided on the organic layer 501. The coating layer 531 may conformally cover the top surface of the organic layer 501. The coating layer 531 may include or may be formed of a dielectric material and may be transparent. The coating layer 531 may include or may be formed of the same material as that of the lens coating layer 530.

The image sensor may further include the circuit chip 20. The circuit chip 20 may be stacked on the sensor chip 10. The circuit chip 20 may include a second wiring layer 1800 and a second substrate 1000. The second wiring layer 1800 may be interposed between the first wiring layer 800 and the second substrate 1000. Integrated circuits 1700 may be located on a top surface or in an inside of the second substrate 1000. The integrated circuits 1700 may include logic circuits, memory circuits, or a combination thereof. The integrated circuits 1700 may include, for example, transistors.

The second wiring layer 1800 may include third interlayer dielectric layers 1820 and second conductive structures 1830. The second conductive structures 1830 may be provided between or in the third interlayer dielectric layers 1820. The second conductive structures 1830 may be electrically connected to the integrated circuits 1700. The second conductive structures 1830 may further include via patterns, and the via patterns and the second conductive structures 1830 may be coupled with each other in the third interlayer dielectric layers 1820.

An external coupling pad 600 may be provided on the pad zone PDR of the first substrate 100. The external coupling pad 600 may be adjacent to the first surface 100a of the first substrate 100. The external coupling pad 600 may be buried in the first substrate 100. For example, a pad trench 990 may be defined on the first surface 100a of the first substrate 100 on the pad zone PDR, and the external coupling pad 600 may be provided in the pad trench 990. The external coupling pad 600 may include or may be formed of metal, such as aluminum, copper, tungsten, titanium, tantalum, and an alloy thereof. In a mounting process of the image sensor, a bonding wire may be formed on and coupled to the external coupling pad 600. The external coupling pad 600 may be electrically connected through the bonding wire to an external apparatus.

A first through hole 901 may be defined adjacent to a first side of the external coupling pad 600. The first through hole 901 may be provided between the external coupling pad 600 and the contact plug 960. The first through hole 901 may penetrate the dielectric layer 400, the first substrate 100, and the first wiring layer 800. The first through hole 901 may further penetrate at least a portion of the second wiring layer 1800. The first through hole 901 may have a first bottom surface and a second bottom surface. The first bottom surface of the first through hole 901 may expose the first conductive structure 830. The second bottom surface of the first through hole 901 may be located at a lower level than that of the first bottom surface of the first through hole 901. The second bottom surface of the first through hole 901 may expose the second conductive structure 1830. For example, the bottom surface of the first through hole 901 may be stepped to have the first bottom surface and the second bottom surface that are disposed at different levels. In some embodiments, the second bottom surface of the first through hole 901 may be located lower than the first bottom surface of the first through hole 901.

The first conductive pattern 911 may extend from the optical black zone OBR onto the pad zone PDR. The first conductive pattern 911 may cover an inner wall of the first through hole 901. The first conductive pattern 911 in the first through hole 901 may be in contact with a top surface of the first conductive structure 830. Therefore, the first conductive structure 830 may be electrically connected through the first conductive pattern 911 to a second separation pattern 220 which will be discussed with reference to FIG. 7.

The first conductive pattern 911 in the first through hole 901 may also be in contact with a top surface of the second conductive structure 1830. The second conductive structure 1830 may be electrically connected through the first conductive pattern 911 to the first conductive structure 830 and the second separation pattern 220.

A first buried pattern 921 may be provided in the first through hole 901, thereby filling the first through hole 901. The first buried pattern 921 may include or may be formed of a low-refractive material and may have dielectric characteristics (i.e., may include or may be formed of an insulating material). The first buried pattern 921 may include or may be formed of the same material as that of the first fence pattern 310. The first buried pattern 921 may have a recess at a top surface thereof. For example, a center of the top surface of the first buried pattern 921 may be lower than an edge of the top surface of the first buried pattern 921.

A first capping pattern 931 may be disposed on the top surface of the first buried pattern 921, thereby filling the recess of the first buried pattern 921. A top surface of the first capping pattern 931 may be substantially flat. The first capping pattern 931 may include or may be formed of a dielectric polymer, such as a photoresist material.

A second through hole 902 may be defined adjacent to a second side of the external coupling pad 600. The second through hole 902 may penetrate the dielectric layer 400, the first substrate 100, and the first wiring layer 800. The second through hole 902 may penetrate a portion of the second wiring layer 1800 and may expose the second conductive structure 1830.

A second conductive pattern 912 may be provided on the pad zone PDR. The second conductive pattern 912 may be provided in the second through hole 902 to conformally cover a sidewall and a bottom surface of the second through hole 902. The second conductive pattern 912 may be electrically connected to the second conductive structure 1830.

The second conductive pattern 912 may be interposed between the external coupling pad 600 and the pad trench 990 to cover a bottom surface and a sidewall of the external coupling pad 600. When the image sensor operates, the integrated circuits 1700 of the circuit chip 20 may transmit and receive electrical signals through the second conductive structure 1830, the second conductive pattern 912, and the external coupling pad 600.

A second buried pattern 922 may be provided in the second through hole 902, thereby filling the second through hole 902. The second buried pattern 922 may include or may be formed of a low-refractive material and may have dielectric characteristics (i.e., may include or may be formed of an insulating material). For example, the second buried pattern 922 may include or may be formed of the same material as that of the first fence pattern 310. The second buried pattern 922 may have a recess on a top surface thereof.

A second capping pattern 932 may be disposed on the top surface of the second buried pattern 922, thereby filling the recess of the second buried pattern 922. A top surface of the second capping pattern 932 may be substantially flat. The second capping pattern 932 may include or may be formed of a dielectric polymer, such as a photoresist material.

The protective dielectric layer 471 may extend from the optical black zone OBR onto the pad zone PDR. The protective dielectric layer 471 may be provided on the top surface of the dielectric layer 400, and may extend into the first through hole 901 and the second through hole 902. In the first through hole 901, the protective dielectric layer 471 may be interposed between the first conductive pattern 911 and the first buried pattern 921. In the second through hole 902, the protective dielectric layer 471 may be interposed between the second conductive pattern 912 and the second buried pattern 922. The protective dielectric layer 471 may expose the external coupling pad 600. In some embodiments, the protective dielectric layer 471 may extend into the first through hole 901 and the second through hole 902 except for the pad trench 990. In the pad trench 990, the protective dielectric layer 471 may not be present between the external coupling pad 600 and the second conductive pattern 912.

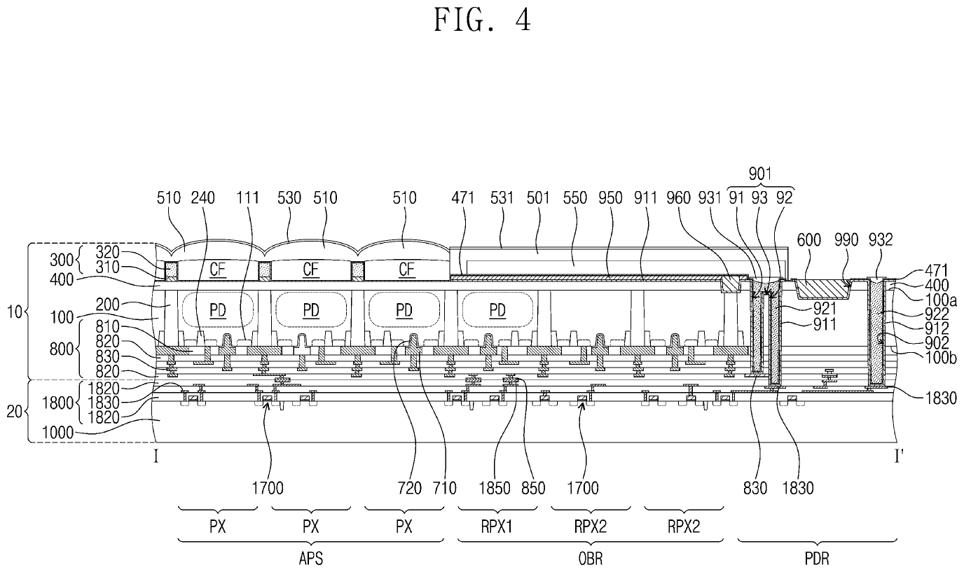

FIG. 4 illustrates a cross-sectional view taken along line I-I′ of FIG. 2 which shows an image sensor according to some embodiments of the present inventive concepts. In the embodiment that follows, a detailed description of technical features repetitive to those discussed above with reference to FIGS. 1 to 3 will be omitted, and a difference thereof will be explained in detail.

Referring to FIGS. 2 and 4, an image sensor may include a sensor chip 10 and a circuit chip 20. The sensor chip 10 may include a first connection pad 850. The first connection pad 850 may be exposed on a bottom surface of the sensor chip 10. The first connection pad 850 may be disposed in a lowermost second interlayer dielectric layer 820. The first connection pad 850 may be electrically connected to the first conductive structure 830. The first connection pad 850 may include or may be formed of a conductive material, such as metal. For example, the first connection pad 850 may include or may be formed of copper. Alternatively, the first connection pad 850 may include at least one of aluminum, tungsten, titanium, and an alloy thereof.

The circuit chip 20 may include a second connection pad 1850. The second connection pad 1850 may be exposed on a top surface of the circuit chip 20. The second connection pad 1850 may be disposed in an uppermost third interlayer dielectric layer 1820. The second connection pad 1850 may be electrically connected to the integrated circuit 1700. The second connection pad 1850 may include or may be formed of a conductive material, such as metal. For example, the second connection pad 1850 may include or may be formed of copper. Alternatively, the second connection pad 1850 may include one or more of aluminum, tungsten, titanium, and an alloy thereof.

The circuit chip 20 and the sensor chip 10 may be connected with each other by direct bonding (e.g., Cu-to-Cu direct bonding). For example, the first connection pad 850 and the second connection pad 1850 may be vertically aligned with each other and may contact with each other. Therefore, the second connection pad 1850 may be directly bonded to the first connection pad 850. As a result, the integrated circuits 1700 of the circuit chip 20 may be electrically connected through the first and second connection pads 850 and 1850 to the external coupling pads 600 or transistors of the sensor chip 10.

The second interlayer dielectric layer 820 may be directly attached to the third interlayer dielectric layer 1820. In this case, a chemical bond may be formed between the second interlayer dielectric layer 820 and the third interlayer dielectric layer 1820.

The first through hole 901 may include a first through hole part 91, a second through hole part 92, and a third through hole part 93. The first through hole part 91 may penetrate the dielectric layer 400, the first substrate 100, and the first wiring layer 800, and may have a first bottom surface. The second through hole part 92 may penetrate the dielectric layer 400, the first substrate 100, and the first wiring layer 800, and may extend into an upper portion of the second wiring layer 1800. The second through hole part 92 may have a second bottom surface, and the second bottom surface may expose the top surface of the second conductive structure 1830. The second bottom surface of the second through hole part 92 may be lower than the first bottom surface of the first through hole part 91. The present invention is not limited thereto. In some embodiments, the second bottom surface of the second through hole part 92 may be higher than the first bottom surface of the first through hole part 91. The second through hole part 92 may have a sidewall spaced apart from that of the first through hole part 91. The third through hole part 93 may be provided between and connected to an upper portion of the first through hole part 91 and an upper portion of the second through hole part 92. The first through hole 901 may be provided therein with the first conductive pattern 911, the protective dielectric layer 471, and the first buried pattern 921. The first conductive pattern 911 may cover inner walls of the first, second, and third through hole parts 91, 92, and 93.

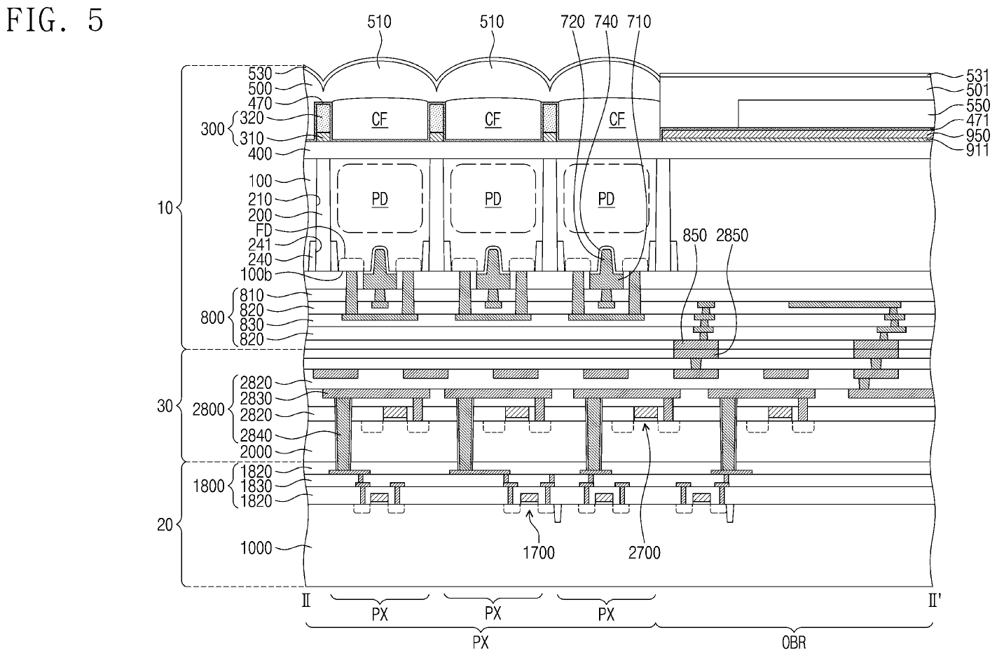

FIG. 5 illustrates a cross-sectional view taken along line II-II′ of FIG. 2 which shows an image sensor according to some embodiments of the present inventive concepts. In the embodiment that follows, a detailed description of technical features repetitive to those discussed with reference to FIGS. 1 to 4 will be omitted, and a difference thereof will be discussed in detail.

Referring to FIGS. 2 and 5, an image sensor may further include a middle chip 30 interposed between the sensor chip 10 and the circuit chip 20. The middle chip 30 may include a third wiring layer 2800 and a third substrate 2000. The third wiring layer 2800 may be interposed between the first wiring layer 800 and the third substrate 2000. The second wiring layer 1800 of the circuit chip 20 may be provided below the third substrate 2000.

The third substrate 2000 may be provided with driver transistors 2700 on a top surface thereof. The driver transistors 2700 may include the conversion gain transistor Cx, the reset transistor Rx, the source follower transistor Sx, and the selection transistor Ax that are discussed with reference to FIG. 1. According to some embodiments, the photoelectric conversion region PD, the transfer transistor Tx, and the floating diffusion region FD of FIG. 1 may be provided in or on the first substrate 100 of the sensor chip 10. The middle chip 30 may be provided on the third substrate 2000 with the conversion gain transistor Cx, the reset transistor Rx, the source follower transistor Sx, and the selection transistor Ax of FIG. 1.

The third wiring layer 2800 may include fourth interlayer dielectric layers 2820 and third conductive structures 2830. The third conductive structures 2830 may be provided between or in the fourth interlayer dielectric layers 2820. The third conductive structures 2830 may be electrically connected to the driver transistors 2700. The third conductive structures 2830 may include contacts, wiring lines, and vias.

The sensor chip 10 may include a first connection pad 850. The first connection pad 850 may be exposed on a bottom surface of the sensor chip 10. The first connection pad 850 may be disposed in a lowermost second interlayer dielectric layer 820. The first connection pad 850 may be electrically connected to the first conductive structure 830.

The middle chip 30 may include a third connection pad 2850. The third connection pad 2850 may be exposed on a top surface of the middle chip 30. The third connection pad 2850 may be disposed in an uppermost fourth interlayer dielectric layer 2820. The third connection pad 2850 may be electrically connected to the driver transistors 2700. The third connection pad 2850 may include or may be formed of a conductive material, such as metal. For example, the third connection pad 2850 may include or may be formed of copper. Alternatively, the third connection pad 2850 may include or may be formed of at least one of aluminum, tungsten, titanium, and an alloy thereof.

The middle chip 30 and the sensor chip 10 may be connected with each other by direct bonding. In some embodiments, the direct bonding may include Cu-to-Cu direct bonding. For example, the first connection pad 850 and the third connection pad 2850 may be vertically aligned with each other and may contact with each other. Therefore, the third connection pad 2850 may be directly bonded to the first connection pad 850. As a result, the driver transistors 2700 of the middle chip 30 may be electrically connected through the first and third connection pads 850 and 2850 to the floating diffusion regions FD of the sensor chip 10.

The second interlayer dielectric layer 820 may be directly attached to the fourth interlayer dielectric layer 2820. In this case, a chemical bond may be formed between the second interlayer dielectric layer 820 and the fourth interlayer dielectric layer 2820.

The middle chip 30 may further include through vias 2840 that penetrate the third substrate 2000. Each of the through vias 2840 may electrically connect the third wiring layer 2800 to the second wiring layer 1800. For example, the middle chip 30 and the circuit chip 20 may be electrically connected with each other through the through vias 2840.

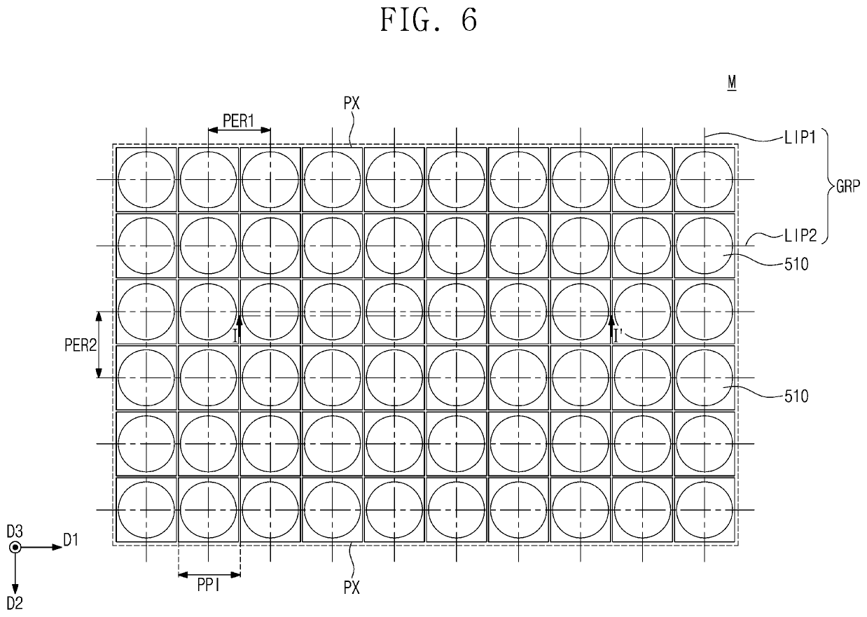

FIG. 6 illustrates a plan view of section M of FIG. 2 which shows an image sensor according to some embodiments of the present inventive concepts. FIG. 7 illustrates a cross-sectional view taken along line I-I′ of FIG. 6. In the embodiment that follows, a detailed description of technical features repetitive to those discussed with reference to FIGS. 1 to 5 will be omitted, and a difference thereof will be discussed in detail. Referring to FIGS. 6 and 7, an image sensor may include a first substrate 100. The image sensor may further include a dielectric layer 400, color filters CF, a fence pattern 300, and a microlens layer 500 that are provided on a first surface 100a of the first substrate 100. In the present embodiment, components below the first substrate 100 are omitted, and a detailed description thereof is as described above with reference to FIGS. 3 to 5.

The pixel array zone APS of the first substrate 100 may include two-dimensionally arranged pixel sections PX. The pixel sections PX may have the same size (or area). Each of the pixel sections PX may include a photoelectric conversion region PD.

A grid-shaped separation pattern 200 may be provided in the first substrate 100. The separation pattern 200 may define the pixel sections PX. For example, the separation pattern 200 may include a first separation pattern 210 and a second separation pattern 220.

The first separation pattern 210 may be interposed between the second separation pattern 220 and the first substrate 100. For example, the first separation pattern 210 may include or may be formed of a dielectric material, such as a silicon oxide layer. The second separation pattern 220 may include or may be formed of a conductive material, such as metal or doped silicon. For example, as discussed above with reference to FIG. 3, the second separation pattern 220 adjacent to the pad zone PDR may be electrically connected to the first conductive pattern 911.

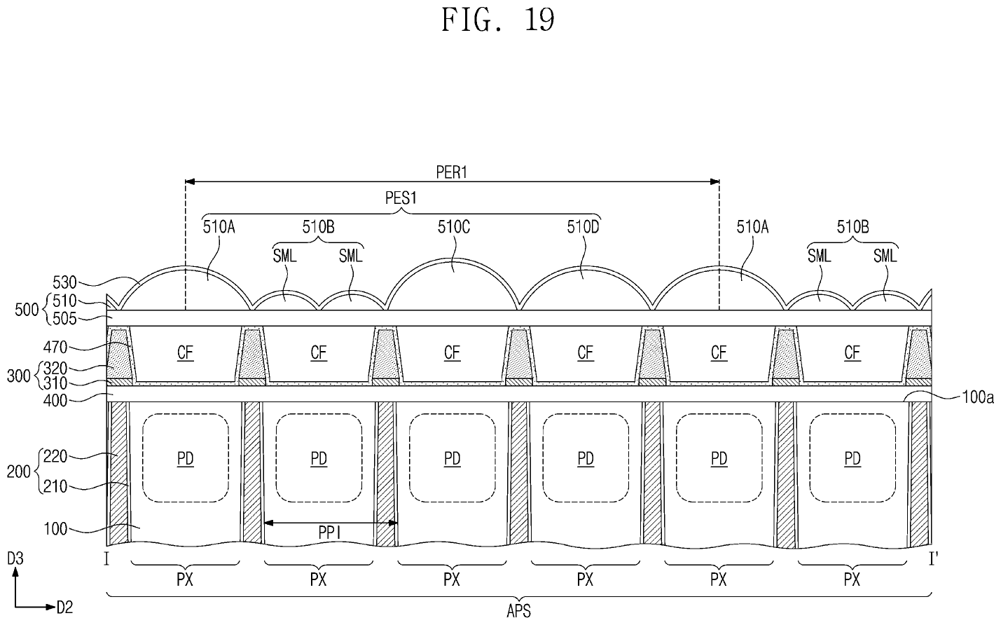

A dielectric layer 400 may be provided on the first surface 100a of the first substrate 100. A color filter CF may be provided on each of the pixel sections PX. The color filter CF may be provided on the dielectric layer 400. The color filter CF may be a red filter, a green filter, a blue filter, a white filter, or a transparent filter. An arrangement of the color filters CF will be discussed below with reference to FIGS. 19 to 26.

A fence pattern 300 may be provided between neighboring color filters CF. A protective layer 470 may be interposed between the fence pattern 300 and the color filters CF.

The color filters CF may be provided thereon with a microlens layer 500 that includes microlenses 510. The microlens layer 500 may include a planarized layer 505 and the microlenses 510. In some embodiments, the planarized layer 505 may include or may be formed of the same material as that of the microlenses 510. Therefore, no boundary may be present between the planarized layer 505 and the microlenses 510. In some embodiments, the planarized layer 505 may include or may be formed of a different material from that of the microlenses 510.

A lens coating layer 530 may be provided on the microlenses 510. The microlenses 510 may be correspondingly provided on the color filters CF. The microlenses 510 may be two-dimensionally arranged. The microlenses 510 may have different sizes from each other. The microlenses 510 may be regularly arranged at a first pitch along the first direction D1. The microlenses 510 may be arranged at a second pitch along the second direction D2. The first pitch and the second pitch may be the same as each other. Each of the first and second pitches may be the same as a pixel pitch PPI of the pixel sections PX.

The microlenses 510 according to some embodiments may have the same size, curvature, material, and shape. In this description, the phrase “the microlenses have the same size” may mean that the microlenses have the same diameter and height. In this description, the phrase “the microlenses have the same curvature” may mean that the microlenses have the same curvature radius. In this description, the phrase “the microlenses have the same material” may mean that the microlenses include the same material and have the same refractive index. In this description, the phrase “the microlenses have the same shape” may mean that the microlenses have the same planar area and shape.

As the microlenses 510 are two-dimensionally arranged, the microlenses 510 may constitute a grid pattern GRP when viewed in a plan view. The grid pattern GRP may include a plurality of first line patterns LIP1 constituted by the microlenses 510 arranged in the second direction D2 and a plurality of second line patterns LIP2 constituted by the microlenses 510 arranged in the first direction D1. The first line patterns LIP1 may extend in the second direction D2, and the second line patterns LIP2 may extend in the first direction D1 while intersecting the first line patterns LIP1.

A pitch between the first line patterns LIP1 may be the same as a first arrangement period PER1 in the first direction D1 of the microlenses 510. A pitch between the second line patterns LIP2 may be the same as a second arrangement period PER2 in the second direction D2 of the microlenses 510. The pitch may be a distance between centers of two microlenses adjacent to each other in the first direction D1 or in the second direction D2.

In some embodiments, the first arrangement period PER1 may be the same as the second arrangement period PER2. Each of the first and second arrangement periods PER1 and PER2 may be the same as the pixel pitch PPI.

Referring back to FIGS. 6 and 7, the grid pattern GRP formed of the microlenses 510 may generate a first diffracted light DFL1 from an incident light ICL. For example, the grid pattern GRP may serve as a diffraction grating, and thus the first diffracted light DFL1 may be produced by constructive and destructive interferences on the microlens 510. The first diffracted light DFL1 may have a first diffraction angle θ1 with respect to the incident light ICL.

The first diffracted light DFL1 may be reflected from an infrared (IR) filter IRF disposed on or above the microlenses 510 to enter another pixel section PX. The first diffracted light DFL1 may be reflected from a top surface of the infrared (IR) filter IRF to travel toward another pixel section PX. The first diffracted light DFL1 may be reflected from a module lens MDL disposed on or above the infrared (IR) filter IRF to enter the pixel section PX.

As a result, the first diffracted light DFL1 may be re-incident on other pixel sections PX, and a noise signal may be generated. The noise signal may be expressed as a petal pattern on an output of the image sensor. A petal flare may be defined to indicate the generation of petal patterns which are noise.

In the image sensor according to the present embodiment, the grid pattern GRP of the microlenses 510 may have extremely small-sized first and second arrangement periods PER1 and PER2. A reduction in arrangement period may cause a reduction in diffraction order of diffracted light generated from the incident light ICL and an increase in diffraction angle of diffracted light generated from the incident light ICL.

For example, in the present embodiment, the first diffracted light DFL1 of only a first diffraction order may be strongly generated from the incident light ICL, and may have the first diffraction angle θ1 greater than about 70°. Thus, the petal flare may be strongly produced in the image sensor of the present embodiment.

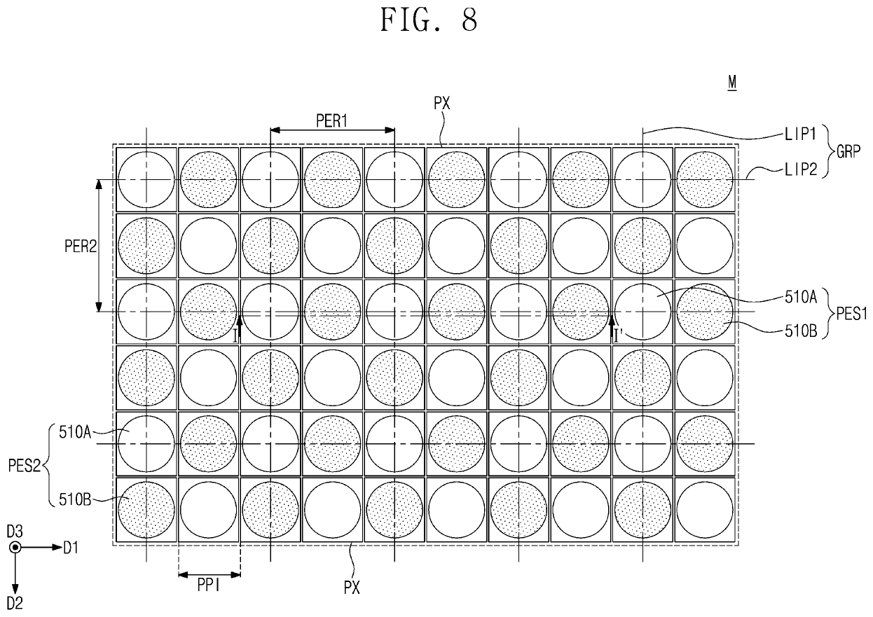

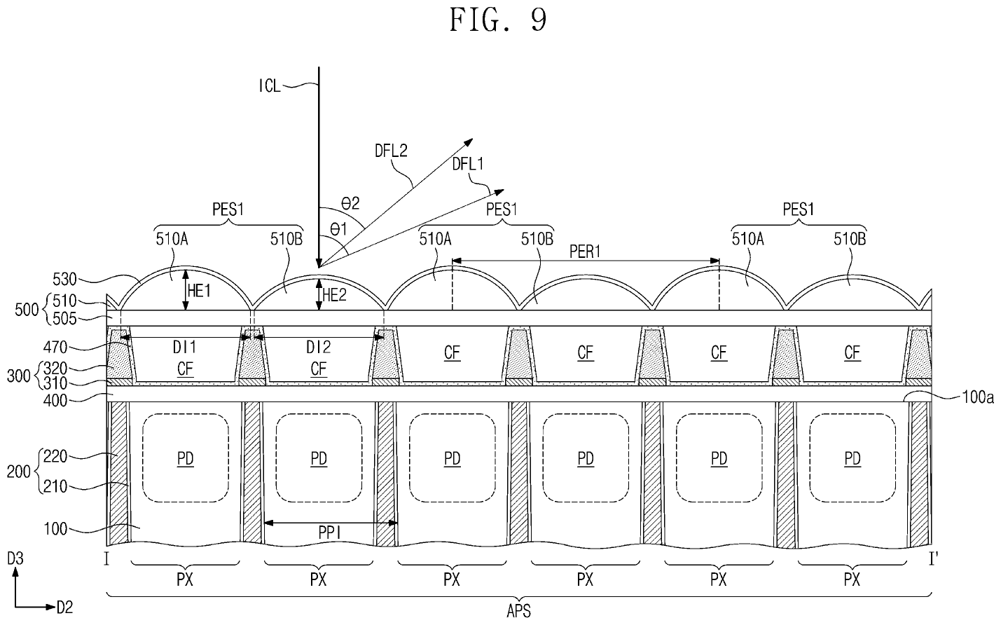

FIG. 8 illustrates a plan view of section M of FIG. 2 which shows an image sensor according to some embodiments of the present inventive concepts. FIG. 9 illustrates a cross-sectional view taken along line I-I′ of FIG. 8. In the embodiment that follows, a detailed description of technical features repetitive to those discussed above with reference to FIGS. 6 and 7 will be omitted, and a difference thereof will be discussed in detail.

Referring to FIGS. 8 and 9, the microlenses 510 according to the present inventive concepts may include first microlenses 510A and second microlenses 510B. The first and second microlenses 510A and 510B may be alternately arranged in the first direction D1. The first and second microlenses 510A and 510B may be repeatedly arranged in the first direction D1 to form a first periodic structure PES1. The first periodic structure PES1 may include one first microlens 510A and one second microlens 510B that are disposed side by side in the first direction D1. A plurality of first periodic structures PES1 may be arranged in the first direction D1.

The first and second microlenses 510A and 510B may be alternately arranged in the second direction D2. The first and second microlenses 510A and 510B may be repeatedly arranged in the second direction D2 to form a second periodic structure PES2. The second periodic structure PES2 may include one first microlens 510A and one second microlens 510B that are disposed side by side in the second direction D2. A plurality of second periodic structures PES2 may be arranged in the second direction D2.

In the present inventive concepts, a periodic structure may be a unit structure of repeatedly arranged microlenses. For example, the first periodic structure PES1 and the second periodic structure PES2 may each be provided in plural, and the plurality of first and second periodic structures PES1 and PES2 may be repeatedly arranged two-dimensionally.

The first microlens 510A and the second microlens 510B may be different from each other. The phrase “the first and second microlenses 510A and 510B are different from each other” may mean that the first and second microlenses 510A and 510B are different from each other in terms of at least one of a size, a curvature, a material, and a shape.

In this description, the phrase “the microlenses have different sizes” may mean that the microlenses have different diameters and heights. In this description, the phrase “the microlenses have different curvatures” may mean that the microlenses have different curvature radii. In this description, the phrase “the microlenses have different materials” may mean that the microlenses have different refractive indices. In this description, the phrase “the microlenses have different shapes” may mean that the microlenses have different planar areas and shapes.

Referring to FIG. 9, the first microlens 510A and the second microlens 510B may have different sizes from each other. The first microlens 510A may have a first diameter DI1, and the second microlens 510B may have a second diameter DI2 less than the first diameter DI1. The first microlens 510A may have a first height HE1. The first height HE1 may be a vertical distance between a top surface of the planarized layer 505 and a crest of the first microlens 510A. The second microlens 510B may have a second height HE2 less than the first height HE1.

Referring to FIGS. 6 and 7, the same microlenses 510 may be arranged such as AAAAAA in the first direction D1, and thus the first arrangement period PER1 of the grid pattern GRP may be the same as a pitch between the microlenses 510. The character “A” represents a type of a microlens, and the repetitive arrangement of AAAAAA means that the microlenses of the repetitive arrangement are the same as each other in terms of a size, a curvature, a material, and a shape. The second arrangement period PER2 of the grid pattern GRP may also be the same as the pitch between the microlenses 510.

Referring to FIGS. 8 and 9, the first and second microlenses 510A and 510B different from each other may be arranged such as ABABAB in the first direction D1, and thus the first arrangement period PER1 of a subsequently described grid pattern GRP may be greater than the first arrangement period PER1 of FIGS. 6 and 7. The characters “A” and “B” indicate different microlenses in terms of at least one of a size, a curvature, a material, and a shape. For example, the first arrangement period PER1 of the present embodiment may be the same as a pitch between first periodic structures that are arranged such as (AB)(AB)(AB). The parenthesis ( ) indicates a unit structure of a periodic structure repeatedly arranged, and the characters in the parenthesis indicate microlenses different from each other in terms of at least one of a size, a curvature, a material, and a shape.

The first and second microlenses 510A and 510B different from each other may be arranged such as ABABAB in the second direction D2, and thus the second arrangement period PER2 of a subsequently described grid pattern GRP may be greater than the second arrangement period PER2 of FIGS. 6 and 7. For example, the second arrangement period PER2 of the present embodiment may be the same as a pitch between second periodic structures that are arranged such as (AB)(AB) (AB).

The first and second periodic structures PES1 and PES2 may be two-dimensionally arranged to constitute a grid pattern GRP. For example, the grid pattern GRP of the present inventive concepts may be defined not by the microlenses 510, but by the first and second periodic structures PES1 and PES2.

In the present embodiment, a pitch between the first line patterns LIP1 may be the same as the first arrangement period PER1, or a pitch in the first direction D1 of the first periodic structures PES1. In the present embodiment, a pitch between the second line patterns LIP2 may be the same as the second arrangement period PER2, or a pitch in the second direction D2 of the second periodic structures PES2.

The first arrangement period PER1 may not be a pitch in the first direction D1 of the microlenses 510, but may be a pitch in the first direction D1 of the first periodic structures PES1. Therefore, the first arrangement period PER1 of the present embodiment may be about twice the first arrangement period PER1 discussed in FIGS. 6 and 7. The first arrangement period PER1 of the present embodiment may be about twice the pixel pitch PPI.

The second arrangement period PER2 may not be a pitch in the second direction D2 of the microlenses 510, but may be a pitch in the second direction D2 of the second periodic structures PES2. Therefore, the second arrangement period PER2 of the present embodiment may be about twice the second arrangement period PER2 discussed in FIGS. 6 and 7. The second arrangement period PER2 of the present embodiment may be about twice the pixel pitch PPI.

The grid pattern GRP formed of the microlenses 510 may generate a first diffracted light DFL1 and a second diffracted light DFL2 from an incident light ICL. The grid pattern GRP according to the present embodiment may have the first and second arrangement periods PER1 and PER2 that are respectively greater than about twice the first and second arrangement periods PER1 and PER2 of the grid pattern GRP shown in FIGS. 6 and 7. Therefore, there may be an increase in diffraction order of diffracted light generated from the incident light ICL and a reduction in diffraction angle of diffracted light generated from the incident light ICL.

For example, in the present embodiment, the first diffracted light DFL1 of a first diffraction order and the second diffracted light DFL2 of a second diffraction order may be generated from the incident light ICL. Because two diffracted rays are generated from one incident light ICL, each of two diffracted rays may have intensity less than that of the first diffracted light DFL1 of FIG. 7. In addition, since the second diffracted light DFL2 may have a second diffraction angle θ2 less than about 70°, there may be a reduction in area of a section on which the second diffracted light DFL2 has an effect.

In an image sensor according to the present embodiment, an arrangement period of the grid pattern GRP may increase to disperse diffracted light generated from incident light and to decrease intensity of the diffracted light. Thus, a small petal flare may weakly occur to reduce its visibility. Accordingly, in the present inventive concepts, an arrangement period of the grid pattern GRP may increase to solve the aforementioned problems of FIGS. 6 and 7.

In the embodiments that follow, a detailed description of technical features repetitive to those discussed above with reference to FIGS. 1 to 7 will be omitted and differences will be discussed in detail.

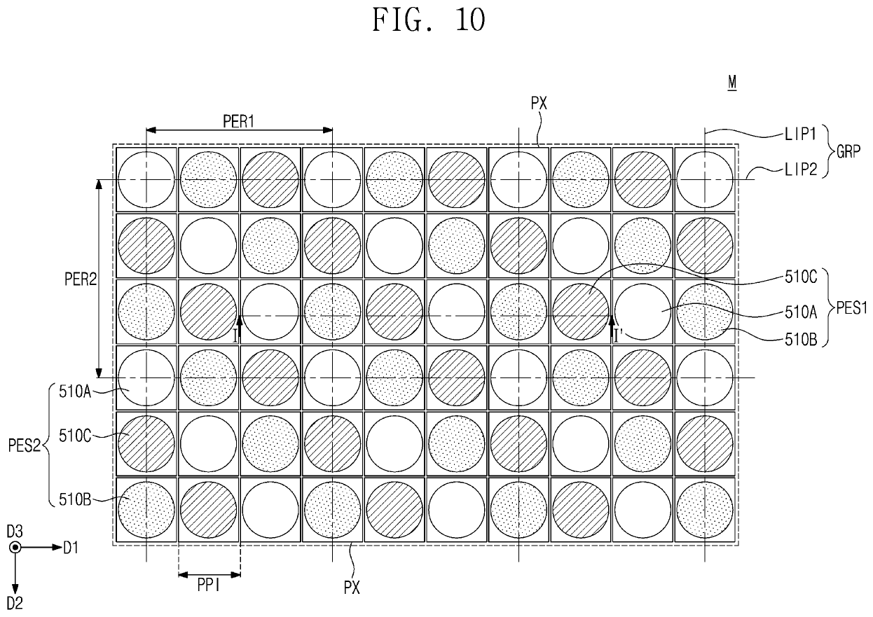

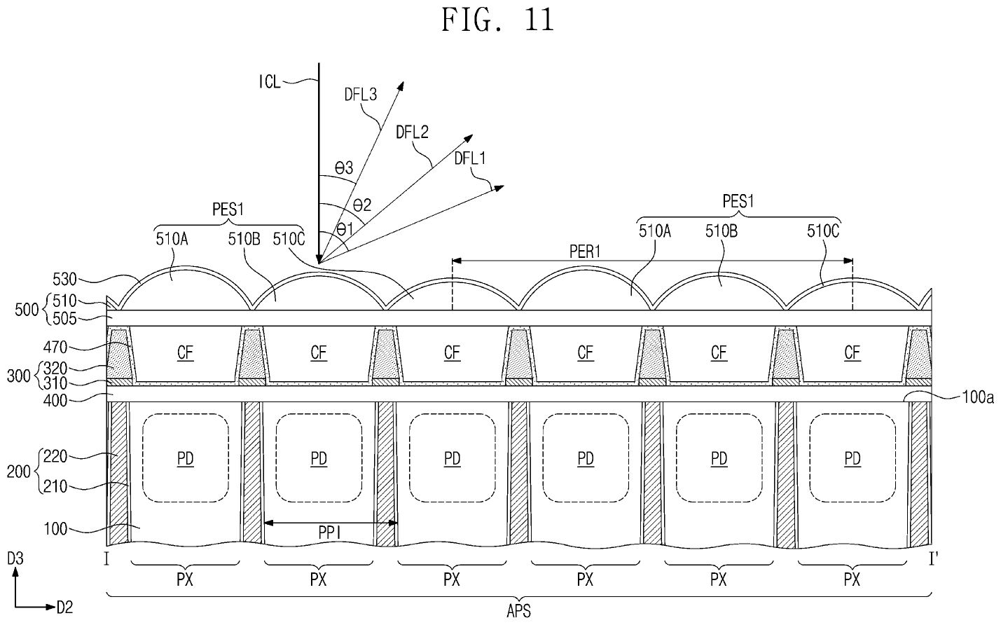

FIG. 10 illustrates a plan view of section M of FIG. 2, showing an image sensor according to some embodiments of the present inventive concepts. FIG. 11 illustrates a cross-sectional view taken along line I-I′ of FIG. 10.

Referring to FIGS. 10 and 11, the microlenses 510 according to the present inventive concepts may include first microlenses 510A, second microlenses 510B, and third microlenses 510C.

The first, second, and third microlenses 510A, 510B, and 510C may be alternately arranged in the first direction D1. The first, second, and third microlenses 510A, 510B, and 510C may be repeatedly arranged in the first direction D1 to form a first periodic structure PES1. The first periodic structure PES1 may include one first microlens 510A, one second microlens 510B, and the third microlens 510C that are disposed side by side in the first direction D1. A plurality of first periodic structures PES1 may be arranged in the first direction D1.

The first, second, and third microlenses 510A, 510B, and 510C may be alternately arranged in the second direction D2. The first, second, and third microlenses 510A, 510B, and 510C may be repeatedly arranged in the second direction D2 to form a second periodic structure PES2. The second periodic structure PES2 may include one first microlens 510A, one second microlens 510B, and the third microlens 510C that are disposed side by side in the second direction D2. A plurality of second periodic structures PES2 may be arranged in the second direction D2.

The first, second, and third microlenses 510A, 510B, and 510C may be different from each other. For example, the first, second, and third microlenses 510A, 510B, and 510C may have different diameters and heights.

The first and second periodic structures PES1 and PES2 may be two-dimensionally arranged to constitute a grid pattern GRP. In the present embodiment, a pitch between the first line patterns LIP1 may be the same as the first arrangement period PER1, or a pitch in the first direction D1 of the first periodic structures PES1. In the present embodiment, a pitch between the second line patterns LIP2 may be the same as the second arrangement period PER2, or a pitch in the second direction D2 of the second periodic structures PES2. Each of the first and second arrangement periods PER1 and PER2 of the present embodiment may be about three times the pixel pitch PPI.

The grid pattern GRP formed of the microlenses 510 may generate a first diffracted light DFL1, a second diffracted light DFL2, and a third diffracted light DFL3 from an incident light ICL. The grid pattern GRP according to the present embodiment may have the first and second arrangement periods PER1 and PER2 that are respectively greater than about twice the first and second arrangement periods PER1 and PER2 of the grid pattern GRP shown in FIGS. 6 and 7. Therefore, there may be an increase in diffraction order of diffracted light generated from the incident light ICL and a reduction in diffraction angle of diffracted light generated from the incident light ICL.

For example, in the present embodiment, the first diffracted light DFL1 of a first diffraction order, the second diffracted light DFL2 of a second diffraction order, and the third diffracted light DFL3 of a third diffraction order may be generated from the incident light ICL. Because three diffracted rays are generated from one incident light ICL, each of three diffracted rays may have intensity much less than that of the first diffracted light DFL1 of FIG. 7. In addition, since the third diffracted light DFL3 may have a third diffraction angle θ3 less than about 40°, there may be a reduction in area of a section on which the third diffracted light DFL3 has an effect.

In an image sensor according to the present embodiment, an arrangement period of the grid pattern GRP may largely increase to greatly disperse diffracted light generated from incident light and to remarkably decrease intensity of the diffracted light. Thus, an extremely small petal flare may occur much weakly and may be dramatically reduced in visibility. Accordingly, in the present inventive concepts, an arrangement period of the grid pattern GRP may increase to solve the aforementioned problems of FIGS. 6 and 7.

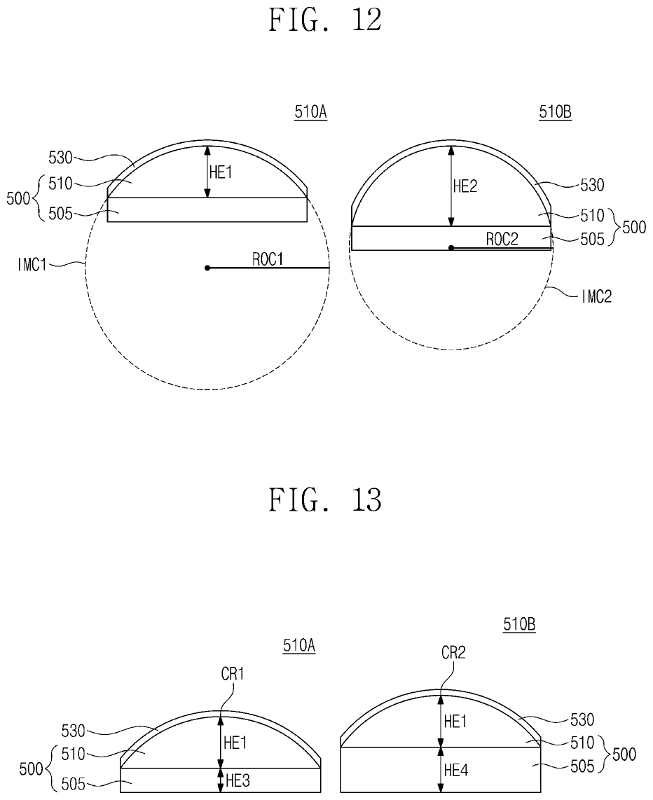

FIGS. 12, 13, and 14 illustrate cross-sectional views showing a difference between a first microlens and a second microlens according to some embodiments of the present inventive concepts.

Referring to FIG. 12, the first microlens 510A and the second microlens 510B may have different curvatures from each other. For example, a first imaginary circle IMC1 may be defined to overlap a surface of the first microlens 510A. A second imaginary circle IMC2 may be defined to overlap a surface of the second microlens 510B. A first radius ROC1 of the first imaginary circle IMC1 may be a first curvature radius of the first microlens 510A, and a second radius ROC2 of the second imaginary circle IMC2 may be a second curvature radius of the second microlens 510B.

The first radius ROC1 of the first microlens 510A may be greater than the second radius ROC2 of the second microlens 510B. For example, the curvature of the first microlens 510A may be less than that of the second microlens 510B. As the first microlens 510A and the second microlens 510B have different curvatures from each other, a height HE1 of the first microlens 510A may be different from a height HE2 of the second microlens 510B when the first microlens 510A and the second microlens 510B have the same width at the bottom.

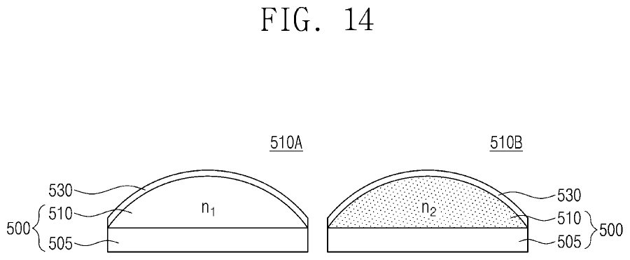

Referring to FIG. 13, a first crest CR1 of the first microlens 510A may be located at a different level from that of a second crest CR2 of the second microlens 510B. For example, the first crest CR1 of the first microlens 510A may be located at a lower level than that of the second crest CR2 of the second microlens 510B.

The first microlens 510A and the second microlens 510B may have the same diameter, height, and curvature. A height HE3 (or thickness) of the planarized layer 505 below the first microlens 510A may be less than a height HE4 (or thickness) of the planarized layer 505 below the second microlens 510B. Therefore, the first crest CR1 of the first microlens 510A may be located at a lower level than that of the second crest CR2 of the second microlens 510B.

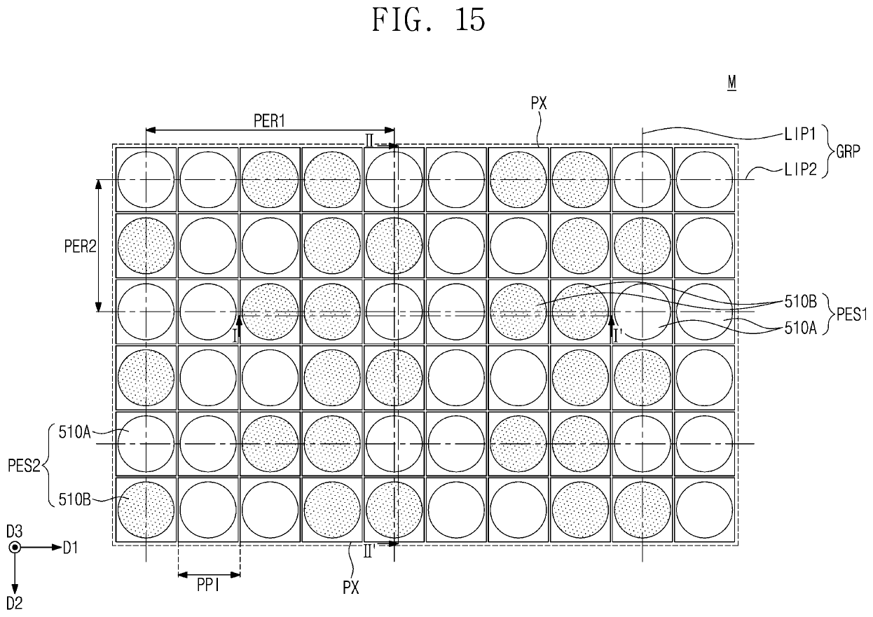

Referring to FIG. 14, the first microlens 510A and the second microlens 510B may have different materials from each other. For example, the first microlens 510A and the second microlens 510B may have the same diameter, height, and curvature. However, a first refractive index n1 of the first microlens 510A may be different from a second refractive index n2 of the second microlens 510B.

As discussed above with reference to FIGS. 12 to 14, in the present inventive concepts, the phrase “microlens are different from each other” may mean that the microlenses are different in terms of at least one of a size, a curvature, a material, and a shape. In the present inventive concepts, microlenses may be different in terms of at least two of a size, a curvature, a material, and a shape.

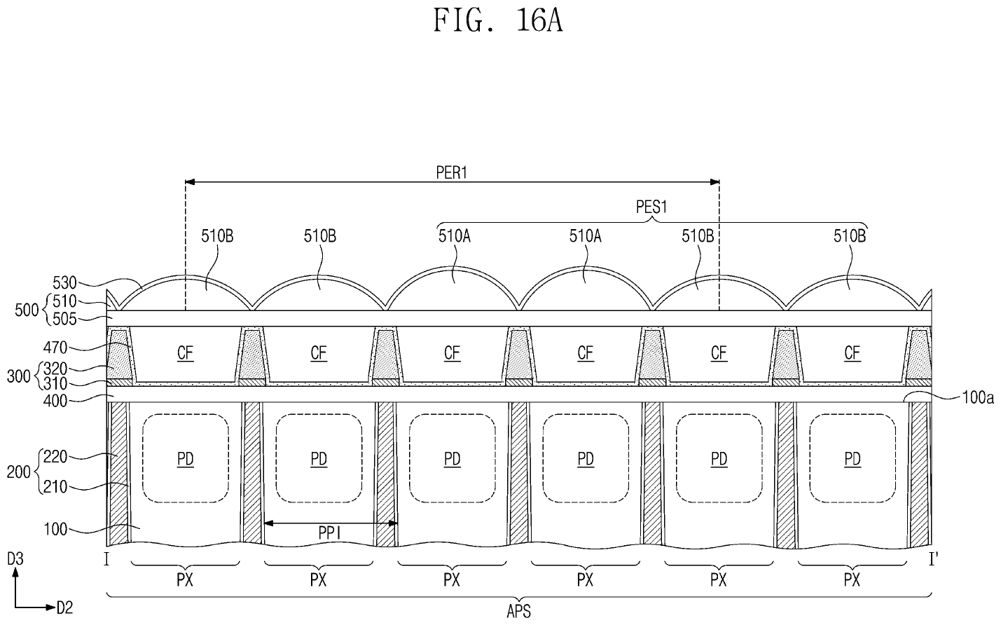

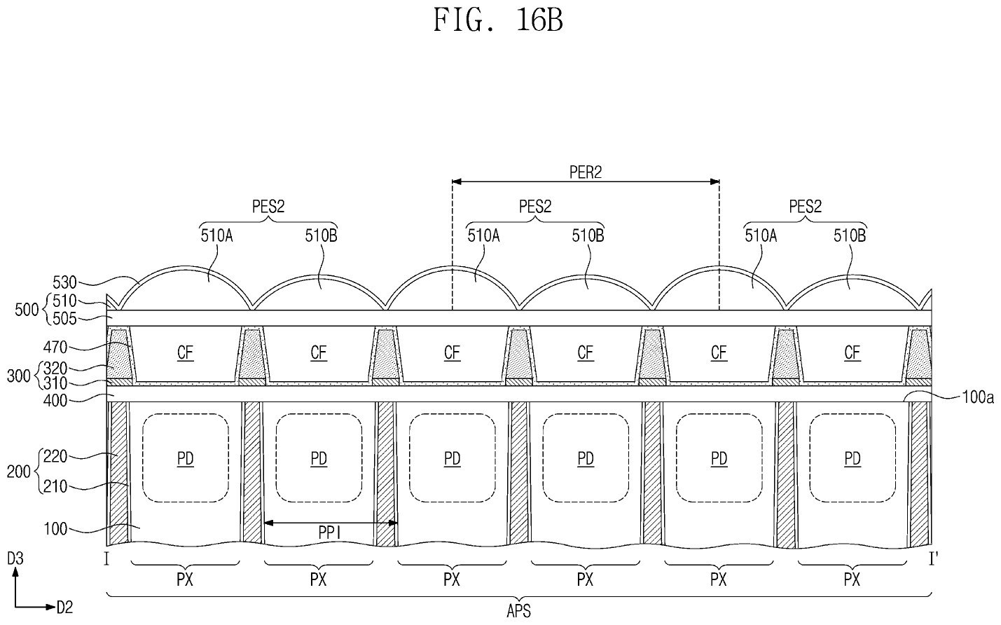

FIG. 15 illustrates a plan view of section M of FIG. 2 which shows an image sensor according to some embodiments of the present inventive concepts. FIG. 16A illustrates a cross-sectional view taken along line I-I′ of FIG. 15. FIG. 16B illustrates a cross-sectional view taken along line II-II′ of FIG. 15.

Referring to FIGS. 15, 16A, and 16B, the first periodic structure PES1 may include two first microlenses 510A and two second microlenses 510B that are sequentially arranged in the first direction D1. The first arrangement period PER1 of the first periodic structures PES1 may be about four times the pixel pitch PPI. For example, in the present embodiment, the first line patterns LIP1 of the grid pattern GRP may have a period (or pitch) of 4×PPI.

The second periodic structure PES2 may include one first microlens 510A and one second microlens 510B that are sequentially arranged in the second direction D2. The second arrangement period PER2 of the second periodic structures PES2 may be about twice the pixel pitch PPI. For example, in the present embodiment, the second line patterns LIP2 of the grid pattern GRP may have a period (or pitch) of 2×PPI.

As disclosed in the present embodiment, the first and second periodic structures PES1 and PES2 of the grid pattern GRP may be different from each other. The first periodic structure PES1 may be N×PPI, and the second periodic structure PES2 may be M×PPI, where each of N and M is an integer equal to or greater than 2, and N and M may be the same as or different from each other.

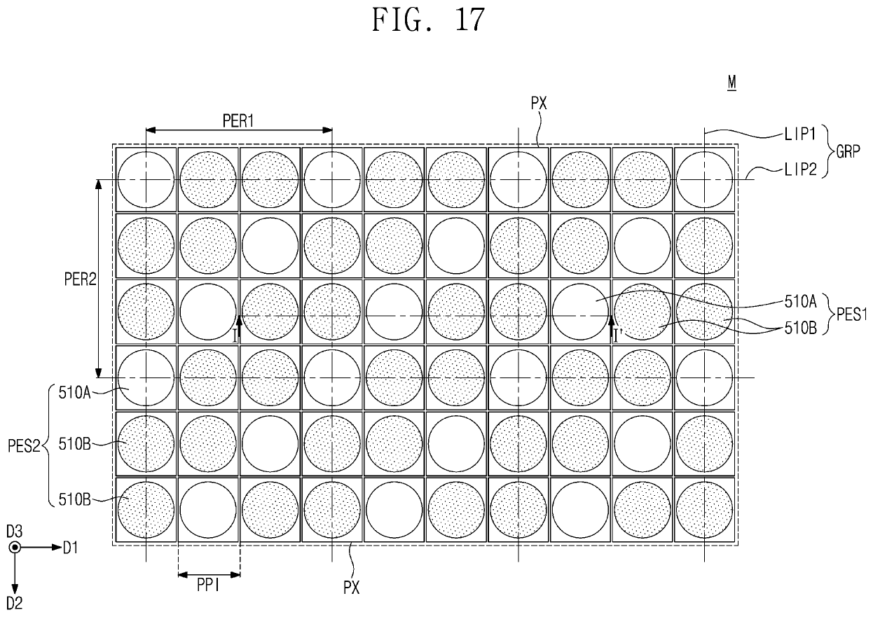

FIG. 17 illustrates a plan view of section M of FIG. 2 which shows an image sensor according to some embodiments of the present inventive concepts. Referring to FIG. 17, the first periodic structure PES1 may include one first microlens 510A and two second microlenses 510B that are sequentially arranged in the first direction D1. The first arrangement period PER1 of the first periodic structures PES1 may be about three times the pixel pitch PPI. For example, in the present embodiment, the first line patterns LIP1 of the grid pattern GRP may have a period (or pitch) of 3×PPI.

The second periodic structure PES2 may include one first microlens 510A and two second microlenses 510B that are sequentially arranged in the second direction D2. The second arrangement period PER2 of the second periodic structures PES2 may be about three times the pixel pitch PPI. For example, in the present embodiment, the second line patterns LIP2 of the grid pattern GRP may have a period (or pitch) of 3×PPI.

Referring to FIGS. 15 and 17, the first periodic structure PES1 according to the present inventive concepts may include at least two first microlenses 510A that are arranged side by side, and/or at least two second microlenses 510B that are arranged side by side. The first periodic structure PES1 may be constituted by N numbers of first microlenses 510A and M numbers of second microlenses 510B that are sequentially arranged. Each N and M may be an integer between 1 and 5. For example, in the case of the first periodic structure PES1 of FIG. 15, each of N and M may be 2. For example, in the case of the first periodic structure PES1 of FIG. 17, N and M may be 1 and 2, respectively. For example, in the case of the first periodic structure PES1 of FIG. 8, each of N and M may be 1. A description of the second periodic structure PES2 may be substantially the same as that of the first periodic structure PES1.

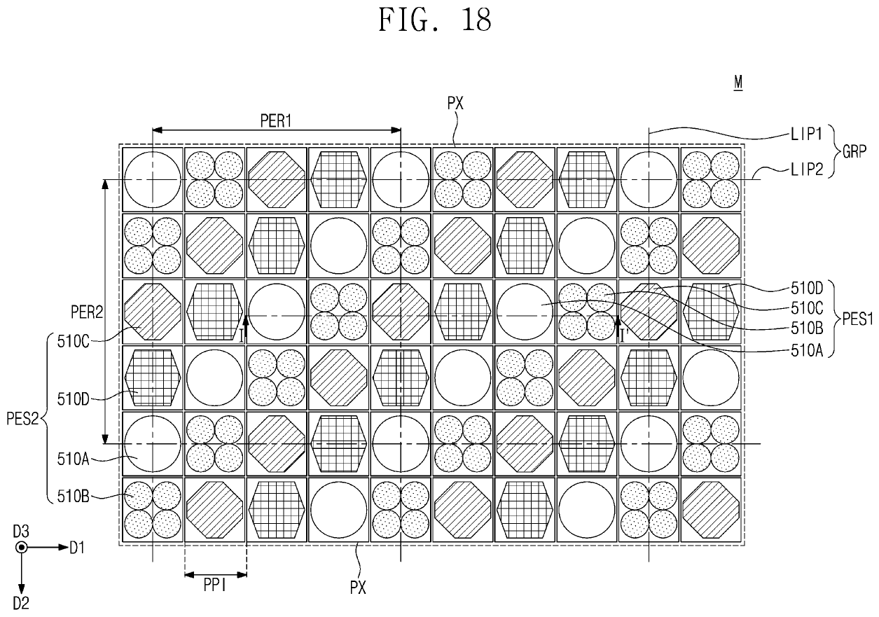

FIG. 18 illustrates a plan view of section M of FIG. 2 which shows an image sensor according to some embodiments of the present inventive concepts. FIG. 19 illustrates a cross-sectional view taken along line I-I′ of FIG. 18.

Referring to FIGS. 18 and 19, the first periodic structure PES1 may include a first microlens 510A, a second microlens 510B, a third microlens 510C, and a fourth microlens 510D that are sequentially arranged in the first direction D1. The first arrangement period PER1 of the first periodic structures PES1 may be about four times the pixel pitch PPI. For example, in the present embodiment, the first line patterns LIP1 of the grid pattern GRP may have a period (or pitch) of 4×PPI.

The second periodic structure PES2 may include a first microlens 510A, a second microlens 510B, a third microlens 510C, and a fourth microlens 510D that are sequentially arranged in the second direction D2. The second arrangement period PER2 of the second periodic structures PES2 may be about four times the pixel pitch PPI. For example, in the present embodiment, the second line patterns LIP2 of the grid pattern GRP may have a period (or pitch) of 4×PPI.

The first to fourth microlenses 510A to 510D according to the present embodiment may have different shapes from each other. For example, the first to fourth microlenses 510A to 510D may have different areas from each other and different planar shapes from each other.

The first microlens 510A may have a circular planar shape. The second microlens 510B may include a plurality of sub-lenses SML. The third microlens 510C may have a polygonal planar shape, for example, an octagonal planar shape. The fourth microlens 510D may have a polygonal planar shape, for example, a hexagonal planar shape.

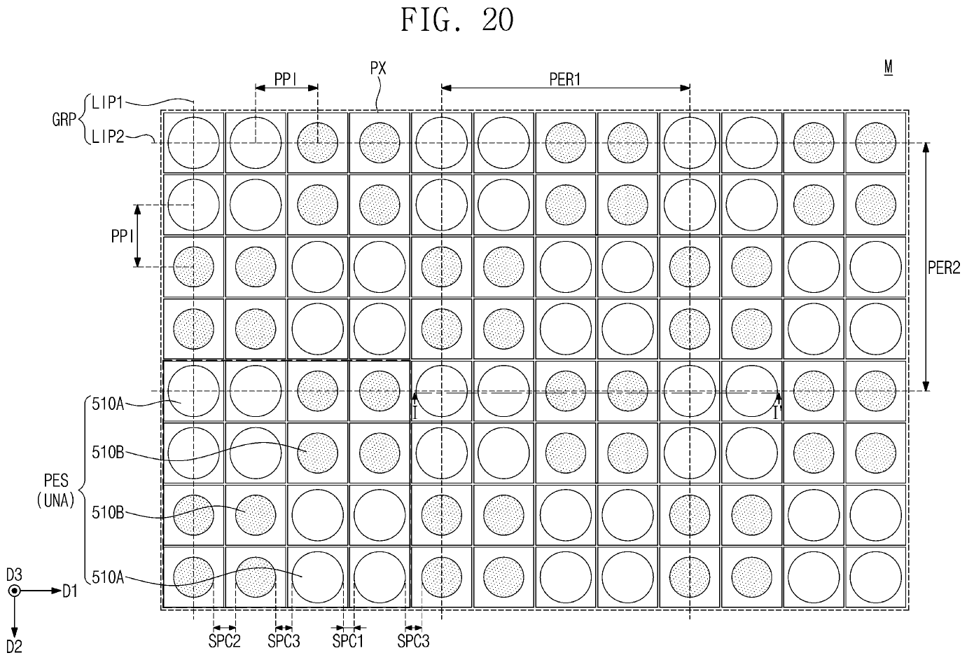

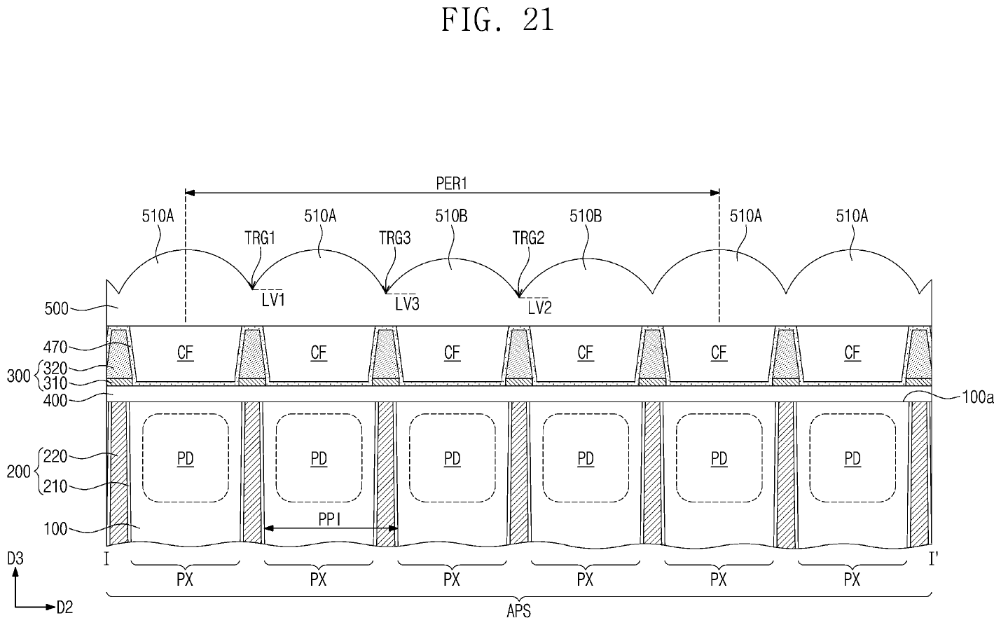

FIG. 20 illustrates a plan view of section M of FIG. 2 which shows an image sensor according to some embodiments of the present inventive concepts. FIG. 21 illustrates a cross-sectional view taken along line I-I′ of FIG. 20.

Referring to FIGS. 20 and 21, the microlenses 510 according to the present inventive concepts may include first microlenses 510A and second microlenses 510B. As discussed above with reference to FIGS. 8 and 9, the first and second microlenses 510A and 510B may have different sizes (or diameters or heights) from each other. For example, the first microlens 510A may have a diameter greater than that of the second microlens 510B. The first microlens 510A may have a height greater than that of the second microlens 510B.

The first microlenses 510A and the second microlenses 510B may be two-dimensionally arranged to constitute a periodic structure PES. The periodic structure PES of the present embodiment may be an N×M lens array UNA. Each of N and M may be an integer equal to or greater than 3. For example, the periodic structure PES may be a 4×4 lens array.

The periodic structure PES may be provided in plural, and the plurality of periodic structures PES may be repeatedly disposed two-dimensionally. For example, the periodic structure PES may be a repetitive array unit of the microlenses 510A and 510B according to the present embodiment.

In some embodiments of the present inventive concepts, the lens array UNA that is the periodic structure PES may include two (2) 2×2 first microlenses 510A and two (2) 2×2 second microlenses 510B.

In some embodiments of the present inventive concepts, the lens array UNA that is the periodic structure PES may include 2×2 first microlenses, 2×2 second microlenses, 2×2 third microlenses, and 2×2 second microlenses. The first to fourth microlenses may have different sizes from each other.

The microlenses 510A and 510B in the periodic structure PES may be arranged at the same pitch PPI. For example, the same pitch PPI may be provided between neighboring first microlenses 510A, between neighboring second microlenses 510B, and between the first microlens 510A and the second microlens 510B that neighbor each other. A center of each of the microlenses 510A and 510B is aligned with a center of the pixel section PX, and thus irrespective of the sizes of the microlenses 510A and 510B, the microlenses 510A and 510B are arranged with the same pitch PPI.

Since the first and second microlenses 510A and 510B have different diameters from each other, there may be a change in interval between neighboring microlenses 510A and 510B. For example, a first spacing SPC1 may be defined to indicate an interval between neighboring first microlenses 510A. A second spacing SPC2 may be defined to indicate an interval between neighboring second microlenses 510B. A third spacing SPC3 may be defined to indicate an interval between the first microlens 510A and the second microlens 510B that neighbor each other. The first, second, and third spacings SPC1, SPC2, and SPC3 may be different from each other. For example, the third spacing SPC3 may be greater than the first spacing SPC1. The second spacing SPC2 may be greater than the third spacing SPC3.

A first arrangement period PER1 may indicate a pitch between the periodic structures PES that are adjacent to each other in the first direction D1. The first arrangement period PER1 of the present embodiment may be about four times the pixel pitch PPI. A second arrangement period PER2 may indicate a pitch between the periodic structures PES that are adjacent to each other in the second direction D2. The second arrangement period PER2 of the present embodiment may be about four times the pixel pitch PPI.

The periodic structures PES may be two-dimensionally arranged such that the microlenses 510 may constitute a grid pattern GRP. The grid pattern GRP may include a plurality of first line patterns LIP1 and a plurality of second line patterns LIP2. The first line patterns LIP1 may extend in the second direction D2, and the second line patterns LIP2 may extend in the first direction D1 while intersecting the first line patterns LIP1.

In the present embodiment, a pitch between the first line patterns LIP1 may be the same as the first arrangement period PER1, or a pitch between the periodic structures PES that are adjacent to each other in the first direction D1. In the present embodiment, a pitch between the second line patterns LIP2 may be the same as the second arrangement period PER2, or a pitch between the periodic structures PES that are adjacent to each other in the second direction D2. Each of the first and second arrangement periods PER1 and PER2 of the present embodiment may be about four times the pixel pitch PPI.

Referring back to FIG. 21, the microlens layer 500 may include a plurality of microlenses 510A and 510B. A trough may be defined between neighboring microlenses 510A and 510B.

For example, a first trough TRG1 may be defined between neighboring first microlenses 510A. A second trough TRG2 may be defined between neighboring second microlenses 510B. A third trough TRG3 may be defined between the first microlens 510A and the second microlens 510B that neighbor each other. The first trough TRG1 may be located at a first level LV1. The second trough TRG2 may be located at a second level LV2. The third trough TRG3 may be located at a third level LV3. The first, second, and third levels LV1, LV2, and LV3 may be different levels from each other. For example, the third level LV3 may be higher than the second level LV2. The first level LV1 may be higher than the third level LV3.

The microlenses 510A and 510B according to the present embodiment may be configured such that the arrangement periods PER1 and PER2 may increase to prevent the petal flare discussed above. As discussed above with reference to FIG. 20, the microlenses 510A and 510B according to the present inventive concepts may have different spacings SPC1 to SPC3. A micro-loading effect may thus force the troughs TRG1 to TRG3 to lie at different levels LV1 to LV3 between the microlenses 510A and 510B. When the troughs TRG1 to TRG3 are located at different levels between the microlenses 510A and 510B as described above, there may be a reduction in optical properties (e.g., signal-to-noise ratio (SNR) and sensitivity) of image sensors.

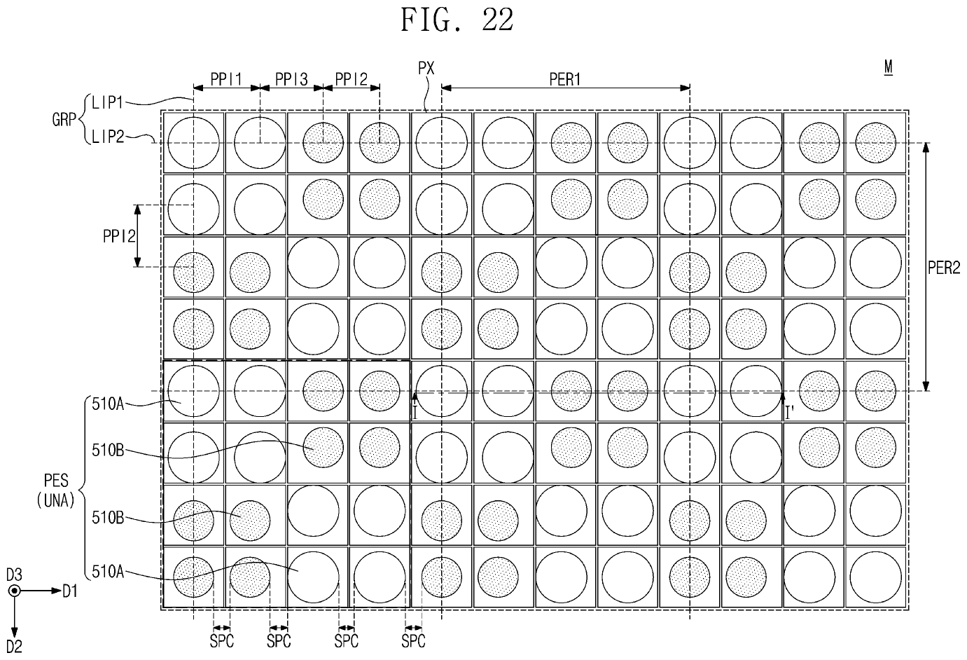

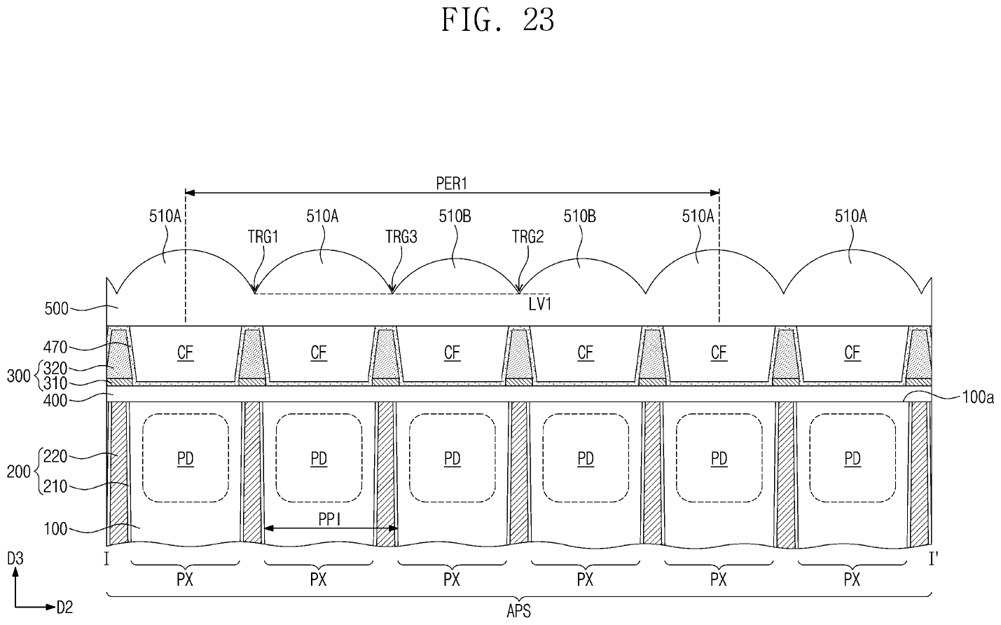

FIG. 22 illustrates a plan view of section M of FIG. 2 which shows an image sensor according to some embodiments of the present inventive concepts. FIG. 23 illustrates a cross-sectional view taken along line I-I′ of FIG. 22. The following will describe in detail an improvement of the embodiment discussed above with reference to FIGS. 20 and 21.

Referring to FIGS. 22 and 23, the microlenses 510A and 510B in the periodic structure PES may be disposed to have the same spacing SPC. For example, the same spacing SPC may be provided between neighboring first microlenses 510A, between neighboring second microlenses 510B, and between the first microlens 510A and the second microlens 510B that neighbor each other. In addition, a spacing between neighboring periodic structures PES may be the same as the spacing SPC between the microlenses 510A and 510B.

To allow the same spacing SPC between the microlenses 510A and 510B, a center of at least one of the microlenses 510A and 510B may be disposed horizontally offset from a center of the pixel section PX on which the at least one microlens is positioned. Therefore, there may be a change in pitch between neighboring microlenses 510A and 510B.

For example, a first pitch PPI1 may indicate a pitch between neighboring first microlenses 510A. A second pitch PPI2 may indicate a pitch between neighboring second microlenses 510B. A third pitch PPI3 may indicate a pitch between the first microlens 510A and the second microlens 510B that neighbor each other. The first, second, and third pitches PPI1, PPI2, and PPI3 may be different from each other. For example, the third pitch PPI3 may be greater than the second pitch PPI2. The first pitch PPI1 may be greater than the third pitch PPI3.

A pitch between the periodic structures PES may be the same as that discussed in FIG. 20. For example, a first arrangement period PER1 may indicate a pitch between the periodic structures PES that are adjacent to each other in the first direction D1, and a second arrangement period PER2 may indicate a pitch between the periodic structures PES that are adjacent to each other in the second direction D2.

Referring back to FIG. 23, a first trough TRG1 may be defined between neighboring first microlenses 510A. A second trough TRG2 may be defined between neighboring second microlenses 510B. A third trough TRG3 may be defined between the first microlens 510A and the second microlens 510B that neighbor each other. The first, second, and third troughs TRG1, TRG2, and TRG3 may be located at the same first level LV1.

For example, the first and second microlenses 510A and 510B may have different heights and diameters, but troughs between the microlenses 510A and 510B may be located at the same level.

The microlenses 510A and 510B according to the present embodiment may be arranged to have the same spacing SPC. A micro-loading effect may thus be prevented and the troughs TRG1 to TRG3 may be positioned at the same level LV1 between the microlenses 510A and 510B. According to the present embodiment, as the troughs TRG1 to TRG3 are located at the same level between the microlenses 510A and 510B, it may be possible to prevent deterioration of optical properties (e.g., signal-to-noise ratio (SNR) and sensitivity) of image sensors.

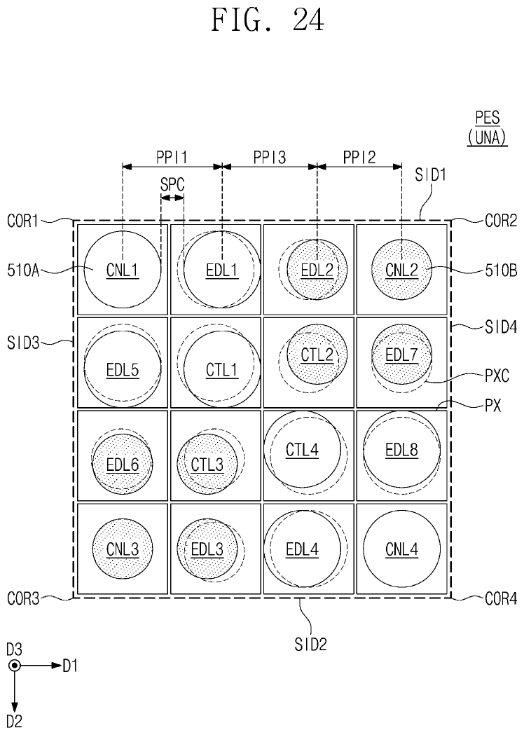

FIG. 24 illustrates an enlarged view showing the periodic structure PES of FIG. 22 according to some embodiments of the present inventive concepts. Referring to FIG. 24, the periodic structure PES may include an array UNA of the microlenses 510A and 510B arranged in a 4×4 arrangement.

The periodic structure PES may include first to fourth sides SID1 to SID4. The first to fourth sides SID1 to SID4 may correspondingly constitute four sides of the array UNA shaped like a tetragon. The first and second sides SID1 and SID2 may be opposite to each other in the second direction D2. The third and fourth sides SID3 and SID4 may be opposite to each other in the first direction D1.

The first and third sides SID1 and SID3 may meet each other to define a first corner COR1. The first and fourth sides SID1 and SID4 may meet each other to define a second corner COR2. The second and third sides SID2 and SID3 may meet each other to define a third corner COR3. The second and fourth sides SID2 and SID4 may meet each other to define a fourth corner COR4.

A first corner lens CNL1, a second corner lens CNL2, a third corner lens CNL3, and a fourth corner lens CNL4 may be respectively disposed on the first, second, third, and fourth corners COR1, COR2, COR3, and COR4 of the periodic structure PES. A center of each of the first to fourth corner lenses CNL1 to CNL4 may be aligned with a pixel center PXC of a corresponding pixel.

A first edge lens EDL1 and a second edge lens EDL2 may be disposed between the first and second corner lenses CNL1 and CNL2. The first and second edge lenses EDL1 and EDL2 may be adjacent to the first side SID1. A center of each of the first and second edge lenses EDL1 and EDL2 may be offset in the first direction D1 from a pixel center PXC of a corresponding pixel.

A third edge lens EDL3 and a fourth edge lens EDL4 may be disposed between the third and fourth corner lenses CNL3 and CNL4. The third and fourth edge lenses EDL3 and EDL4 may be adjacent to the second side SID2. A center of each of the third and fourth edge lenses EDL3 and EDL4 may be offset from a pixel center PXC of a corresponding pixel in a direction reverse to the first direction D1 (i.e., in an opposite direction of the first direction D1).

A fifth edge lens EDL5 and a sixth edge lens EDL6 may be disposed between the first and third corner lenses CNL1 and CNL3. The fifth and sixth edge lenses EDL5 and EDL6 may be adjacent to the third side SID3. A center of each of the fifth and sixth edge lenses EDL5 and EDL6 may be offset in the second direction D2 from a pixel center PXC of a corresponding pixel.

A seventh edge lens EDL7 and an eighth edge lens EDL8 may be disposed between the second and fourth corner lenses CNL2 and CNL4. The seventh and eighth edge lenses EDL7 and EDL8 may be adjacent to the fourth side SID4. A center of each of the seventh and eighth edge lenses EDL7 and EDL8 may be offset from a pixel center PXC of a corresponding pixel in a direction reverse to the second direction D2 (i.e., in an opposite direction of the second direction D2).

First to fourth center lenses CTL1 to CTL4 arranged in a 2×2 arrangement may be disposed on a center of the periodic structure PES. A center of each of the first to fourth center lenses CTL1 to CTL4 may be offset in a direction (e.g., a diagonal direction) that intersects both of the first and second directions D1 and D2.

A center of each of microlenses in the periodic structure PES according to the present embodiment may be horizontally offset based on displacement position, and thus it may be possible to keep the same spacing SPC between the microlenses. For example, among the microlenses in the periodic structure PES, only centers of the first to fourth corner lenses CNL1 to CNL4 may be aligned with the pixel centers PXC of first to fourth corner pixels in the periodic structure PES, and centers of other microlenses may be horizontally offset from the pixel centers PXC of the other pixels in the periodic structure PES. For example, centers of the first and second edge lenses EDL1 and EDL2 may be offset in the first direction D1, but centers of the third and fourth edge lenses EDL3 and EDL4 that stands opposite to the first and second edge lenses EDL1 and EDL2 may be offset in a direction reverse to the first direction D1.

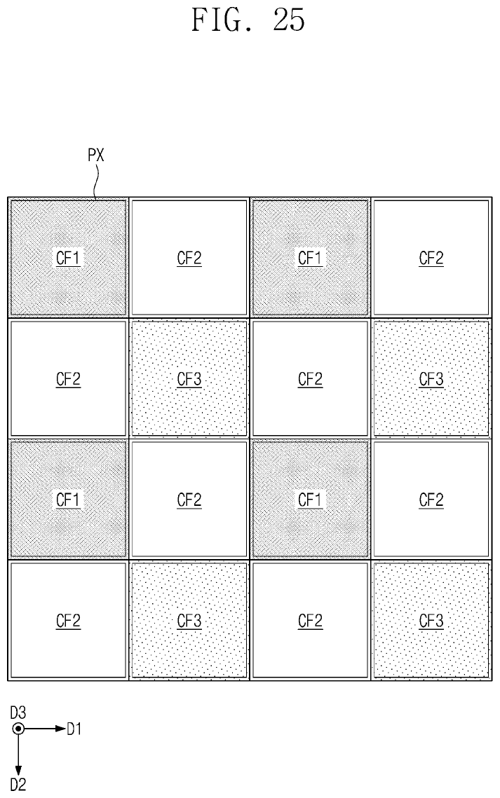

FIGS. 25, 26, and 27 illustrate plan views showing an arrangement of color filters in an image sensor according to some embodiments of the present inventive concepts.

Referring to FIG. 25, the color filters CF may include first, second, and third color filters CF1, CF2, and CF3 arranged in a 2×2 arrangement. The color filters CF arranged in a 2×2 arrangement may include one first color filter CF1, two second color filters CF2, and one third color filter CF3. The 2×2 arranged color filters CF may be two-dimensionally arranged in Bayer pattern format. For example, the first color filter CF1 may be red, the second color filter CF2 may be green, and the third color filter CF3 may be blue.

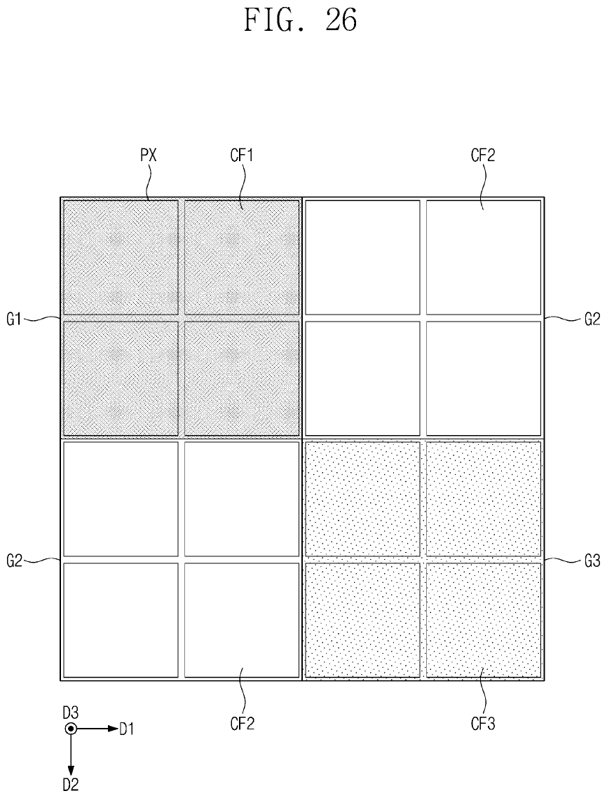

Referring to FIG. 26, first, second, and third pixel groups G1, G2, and G3 may be provided. The first pixel group G1 may detect a first light, the second pixel groups G2 may detect a second light, and the third pixel group G3 may detect a third light.

Each of the first, second, and third pixel groups G1, G2, and G3 may include N×M numbers of pixel sections PX arranged in an N×M arrangement. Symbols N and M may independently be an integer greater than 1. An image sensor according to the present embodiment may have a 2×2 Tetra pixel arrangement where each of N and M is 2.

The first pixel group G1 may include a first color filter CF1, each of the second pixel groups G2 may include a second color filter CF2, and the third pixel group G3 may include a third color filter CF3. For example, the first color filter CF1 may be red, the second color filter CF2 may be green, and the third color filter CF3 may be blue.

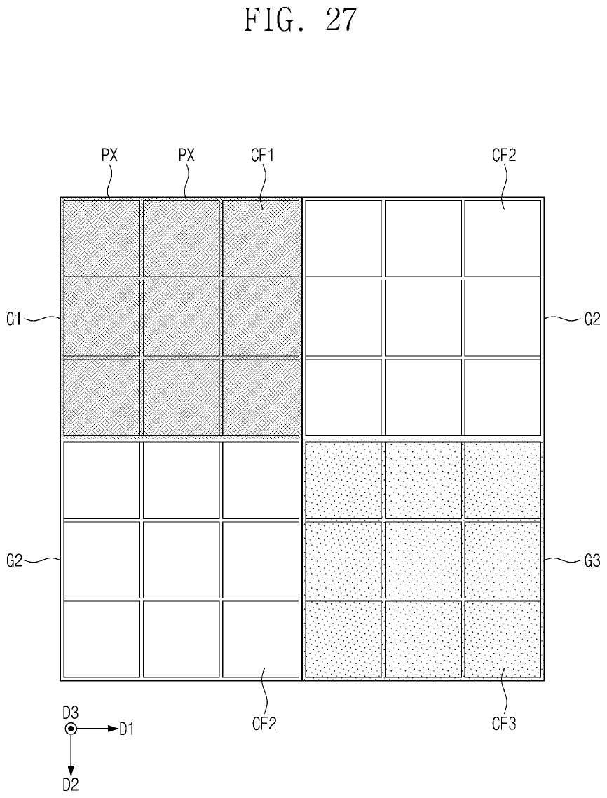

Referring to FIG. 27, each of the first, second, and third pixel groups G1, G2, and G3 may include N×M numbers of pixel sections PX arranged in an N×M arrangement. An image sensor according to the present embodiment may have a 3×3 Nona pixel arrangement where each of N and M is 3.

In the present inventive concepts, a repetitive periodic structure constituted by different microlenses with no change in pixel size may be used to increase a repetitive period of a grid pattern that generates diffracted light. It may thus be possible to avoid a reduction in visibility and to solve a noise problem caused by petal flare expressed on an image (output).

Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope and spirit of the present inventive concepts.

What is claimed is:

1. An image sensor, comprising:
a first substrate including a plurality of pixel sections each of which includes a photoelectric conversion region;
a plurality of color filters on the plurality of pixel sections and on a first surface of the first substrate; and
a plurality of microlenses on the plurality of color filters,
wherein the plurality of microlenses are arranged in an array of the microlenses with a periodic structure,
wherein the periodic structure includes a first microlens, a second microlens, and a third microlens that are sequentially arranged adjacent to each other along a first direction,
wherein a first spacing in the first direction between the first and second microlenses is substantially the same as a second spacing in the first direction between the second and third microlenses, and
wherein a first pitch in the first direction between the first and second microlenses is different from a second pitch in the first direction between the second and third microlenses.

2. The image sensor of claim 1,
wherein a size of the third microlens is different from a size of the first microlens.

3. The image sensor of claim 2,
wherein the size of the third microlens is different from a size of the second microlens.

4. The image sensor of claim 1, wherein:
the first, second, and third microlenses are on first, second, and third pixels, respectively,
the first, second, and third microlenses are arranged along a first side of the periodic structure,
the first microlens is adjacent to a corner of the periodic structure,
a center of the first microlens is aligned with a center of the first pixel, and
a center of the second microlens is offset from a center of the second pixel.

5. The image sensor of claim 4,
wherein a center of the third microlens is offset from a center of the third pixel.

6. The image sensor of claim 4,
wherein the periodic structure further includes a fourth microlens spaced apart from the first to third microlenses,
wherein the fourth microlens is adjacent to a second side of the periodic structure that is parallel to the first side of the periodic structure,
wherein the fourth microlens is on a fourth pixel,
wherein a center of the second microlens is offset in the first direction from the center of the second pixel, and
wherein a center of the fourth microlens is offset from a center of the fourth pixel in an opposite direction of the first direction.

7. The image sensor of claim 1, wherein:
a first trough is defined between the first and second microlenses,
a second trough is defined between the second and third microlenses, and
the first trough and the second trough are at substantially the same level.

8. The image sensor of claim 7,
wherein a height of the third microlens is different from a height of the first microlens.

9. The image sensor of claim 8,
wherein the height of the third microlens is different from a height of the second microlens.

10. The image sensor of claim 1, further comprising:
a plurality of transistors disposed at a second surface of the first substrate, the second surface being opposite to the first surface;
a first wiring layer on the second surface;
a second substrate; and
a second wiring layer on the second substrate,
wherein the first wiring layer and the second wiring layer are vertically stacked and electrically connected with each other.

11. An image sensor, comprising:
a substrate including a plurality of pixel sections each of which includes a photoelectric conversion region;
a plurality of color filters on the plurality of pixel sections and on a first surface of the substrate; and
a plurality of microlenses on the plurality of color filters,
wherein the plurality of microlenses include a first microlenses and a second microlenses, the first and second microlenses having different sizes from each other,
wherein the first and second microlenses constitute a periodic structure of an M×N array, each of M and N being an integer equal to or greater than 3, and
wherein the periodic structure includes:
a first edge lens that is adjacent to a first side of the periodic structure and that is offset in a first direction from a pixel center of a first pixel corresponding to the first edge lens; and
a second edge lens that is adjacent to a second side of the periodic structure and that is offset from a pixel center of a second pixel corresponding to the second edge lens in an opposite direction of the first direction.

12. The image sensor of claim 11, wherein:
the first side and the second side are opposite to each other in a second direction, and
the second direction intersects the first direction.

13. The image sensor of claim 11,
wherein the periodic structure further includes first to fourth corner lenses that are adjacent to four corners of the periodic structure, respectively, and
wherein each of the first to fourth corner lenses in the periodic structure is aligned with a pixel center of a corresponding pixel.

14. The image sensor of claim 11,
wherein the periodic structure further includes:
a third edge lens that is adjacent to a third side of the periodic structure and that is offset in a second direction from a pixel center of a third pixel corresponding to the third edge lens; and
a fourth edge lens that is adjacent to a fourth side of the periodic structure and that is offset from a pixel center of a fourth pixel corresponding to the fourth edge lens in an opposite direction of the second direction, and wherein the second direction intersects the first direction.

15. The image sensor of claim 14,
wherein the periodic structure further includes:
a center lens that is disposed on a center of the periodic structure and that is offset in a third direction from a pixel center of a fifth pixel corresponding to the center lens, the third direction intersecting the first direction and the second direction.

16. An image sensor, comprising:
a circuit chip; and
an image sensor chip on the circuit chip,
wherein the image sensor chip includes:
a first substrate that has a first surface and a second surface that are opposite to each other and includes a plurality of photoelectric conversion regions;
a separation pattern disposed in the first substrate and defining a plurality of pixel sections, the plurality of photoelectric conversion regions being correspondingly provided in the plurality of pixel sections;
a dielectric layer that covers the first surface;
a plurality of color filters disposed on the dielectric layer;
a fence pattern that divides the plurality of color filters;
a protective layer disposed between the fence pattern and each of the plurality of color filters;
a plurality of microlenses disposed on the plurality of color filters;
a lens coating layer on the plurality of microlenses;
a device isolation pattern adjacent to the second surface, the device isolation pattern defining an active region;
a buried gate pattern disposed on the second surface; and
a first wiring layer disposed on the buried gate pattern,
wherein the circuit chip includes:
a second substrate on which a plurality of integrated circuits are provided; and
a second wiring layer on the second surface,
wherein the first wiring layer and the second wiring layer are electrically connected with each other while facing each other,
wherein the plurality of microlenses constitute a periodic structure of an M×N array, each of M and N being an integer equal to or greater than 3,
wherein a center of a first microlens of the periodic structure is offset in a first direction from a pixel center of a first pixel corresponding to the first microlens, and
wherein a center of a second microlens of the periodic structure is offset from a pixel center of a second pixel corresponding to the second microlens in an opposite direction of the first direction.

17. The image sensor of claim 16,
wherein a center of a third microlens of the periodic structure is aligned with a pixel center of a third pixel corresponding to the third microlens.

18. The image sensor of claim 16,
wherein the periodic structure constitutes a grid pattern configured to generate a plurality of diffracted rays from an incident ray.

19. The image sensor of claim 16,
wherein the first and second microlenses are different from each other in terms of at least one of a size, a curvature, a material, and a shape.

20. The image sensor of claim 16, wherein:
a height of the first microlens is different from a height of the second microlens,
a first trough is defined on one side of the first microlens,
a second trough is defined on one side of the second microlens, and
the first trough and the second trough are at substantially the same level.
